(19) United States
(12) Patent Application Publication
(10) Pub. No.: US 2023/0309303 A1
(43) Pub. Date: Sep. 28, 2023

(54) SEMICONDUCTOR MEMORY DEVICE AND METHOD FOR MANUFACTURING SEMICONDUCTOR MEMORY DEVICE

(71) Applicant: Kioxia Corporation, Tokyo (JP)

(72) Inventors: Yusuke MORIKAWA, Yokkaichi (JP); Tatsufumi HAMADA, Nagoya (JP); Tomohiro KUKI, Yokkaichi (JP); Yosuke MITSUNO, Yokkaichi (JP)

(73) Assignee: Kioxia Corporation, Tokyo (JP)

(21) Appl. No.: 17/929,428

(22) Filed: Sep. 2, 2022

(30) Foreign Application Priority Data
Mar. 23, 2022 (JP) 2022-046753

(51) Int. Cl. H01L 27/11582

(52) U.S. Cl. CPC H01L 27/11582

(57) ABSTRACT

A semiconductor memory device includes a substrate, a layer stack, and a pillar. The layer stack is in a first direction above the substrate. The pillar penetrates the layer stack in the first direction. The layer stack includes a first conductor and a first insulator on an upper surface of the first conductor along the first direction. The pillar includes a second insulator extending along an extending direction of the pillar. The second insulator includes a first part located in a first layer in which the first conductor is located and a second part located in a second layer in which the first insulator is located. The first part includes a portion thicker than the second part. A diameter of the pillar in the first layer is larger than a diameter of the pillar in the second layer.

### CROSS-REFERENCE TO RELATED APPLICATIONS

This application is based upon and claims the benefit of priority from Japanese Patent Application No. 2022-046753, filed Mar. 23, 2022, the entire contents of which are incorporated herein by reference.

### FIELD

Embodiments described herein relate generally to a semiconductor memory device and a method for manufacturing a semiconductor memory device.

### BACKGROUND

NAND flush memories are known which can store data in a non-volatile way.

### BRIEF DESCRIPTION OF THE DRAWINGS

FIG. 1 is a block diagram that is a configuration example of a semiconductor memory device 1 according to a first embodiment;

FIG. 2 shows a circuit diagram that is an example of a circuit configuration of a memory cell array included in the semiconductor memory device 1 according to the first embodiment;

FIG. 3 shows a plan view that is an example of a plan layout of the semiconductor memory device 1 according to the first embodiment;

FIG. 4 shows a cross-sectional view taken along line IV-IV of FIG. 3, which is an example of a cross-sectional structure of the memory cell array included in the semiconductor memory device 1 according to the first embodiment;

FIG. 5 shows an enlarged view of a region V of FIG. 4, which is an example of a cross-sectional structure of a memory pillar MP in the semiconductor memory device 1 according to the first embodiment;

FIG. 6 is a conceptual diagram showing a thickness of an insulating film 44;

FIG. 7 shows a cross-sectional view taken along line VII-VII of FIG. 5, which is an example of the cross-sectional structure of the memory pillar MP in the semiconductor memory device 1 according to the first embodiment;

FIG. 8 shows a flowchart which is an example of a manufacturing method of the semiconductor memory device 1 according to the first embodiment;

FIGS. 9 to 21 show examples of cross-sectional structures in the middle of manufacturing the semiconductor memory device 1 according to the first embodiment;

FIG. 22 shows an example of a cross-sectional structure of a memory pillar MPr in a semiconductor memory device 1r according to a comparative example of the first embodiment;

FIG. 23 shows an example of the cross-sectional structure of the memory pillar MP in the semiconductor memory device 1 according to the first embodiment;

FIG. 24 shows an example of a cross-sectional structure of a memory pillar MP in the semiconductor memory device 1 according to a modified example of the first embodiment;

FIG. 25 shows an example of a cross-sectional structure of a memory pillar MPb in a semiconductor memory device 1b according to a second embodiment; and

FIG. 26 shows a cross-sectional view taken along line XXVI-XXVI of FIG. 25, which is an example of the cross-sectional structure of the memory pillar MPb in the semiconductor memory device 1b according to the second embodiment.

### DETAILED DESCRIPTION

A semiconductor memory device includes a substrate, a layer stack, and a pillar. The layer stack is in a first direction above the substrate. The pillar penetrates the layer stack in the first direction. The layer stack includes a first conductor and a first insulator on an upper surface of the first conductor along the first direction. The pillar includes a second insulator extending along an extending direction of the pillar. The second insulator includes a first part located in a first layer in which the first conductor is located and a second part located in a second layer in which the first insulator is located. The first part includes a portion thicker than the second part. A diameter of the pillar in the first layer is larger than a diameter of the pillar in the second layer.

The embodiments will be described below with reference to the drawings. In the following description, components having substantially the same function and configuration are designated by the same reference numeral, and repeated description thereof may be omitted. Additional digits or letters may be added to the end of the reference numeral to distinguish from each other a plurality of components having substantially the same function and configuration.

The drawings are schematic, and the relationship between a thickness and a plane dimension, the ratios of thicknesses of layers, and the like may differ from the actual ones. Therefore, specific thicknesses and dimensions should be determined in consideration of the following explanation. In addition, parts in which mutual relationships or ratios of dimensions differ in between drawings may be contained. All descriptions of one embodiment are also applied as descriptions of another embodiment, unless explicitly or expressly excluded. Each embodiment exemplifies an apparatus or a method for embodying the technical idea of this embodiment, and the technical idea of the embodiment does not specify the material, shape, structure, arrangement, etc. of the component parts to the following.

Although “substantially the same,” “approximately the same,” “substantially constant,” and “substantially uniform” are intended to be the same herein, they refer to allowing errors as well as not being exactly the same due to the limitations of manufacturing and/or measurement techniques.

### [1] First Embodiment

[1-1] Configuration (Structure)

Hereinafter, the semiconductor memory device 1 according to the embodiment will be described.

[1-1-1] Configuration of Semiconductor Memory Device 1

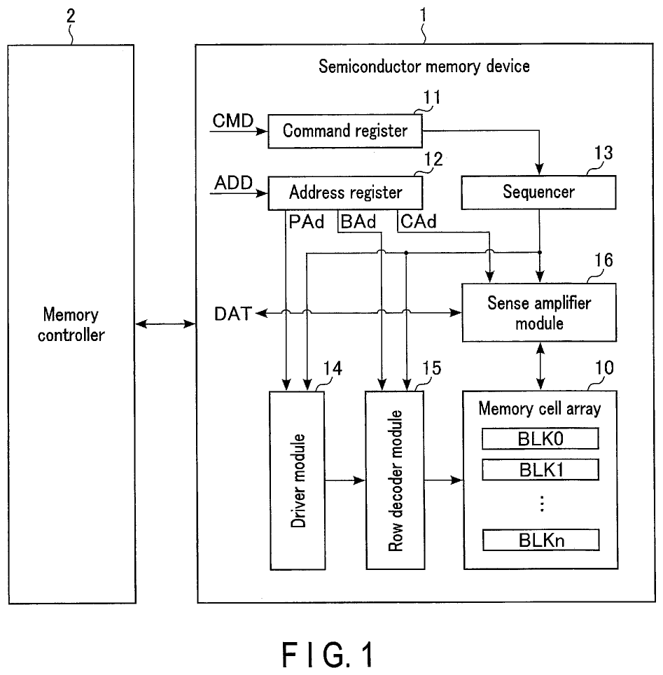

FIG. 1 shows a configuration example of the semiconductor memory device 1 according to the first embodiment. The semiconductor memory device 1 is a NAND flash memory capable of storing data in anon-volatile way. The semiconductor memory device 1 is controlled by an external memory controller 2.

As shown in FIG. 1, the semiconductor memory device 1 includes, for example, a memory cell array 10, a command register 11, an address resister 12, a sequencer 13, a driver module 14, a row decoder module 15, and a sense amplifier module 16.

The memory cell array 10 includes a plurality of blocks BLK 0 to BLK n (n is an integer of 1 or more). Each block BLK includes a plurality of sets of memory cell transistors MT (not shown) capable of storing data in a non-volatile way, and is used as an erasing unit of data, for example. A plurality of source lines SL, word lines WL, bit lines BL, and the like (not shown) are connected to the memory cell array 10. Each memory cell transistor MT is associated with, for example, one bit line BL and one word line WL. The detailed configuration of the memory cell array 10 will be described later.

The command register 11 holds a command CMD received by the semiconductor memory device 1 from the memory controller 2. The command CMD includes, for example, an instruction to cause the sequencer 13 to execute a read operation, a write operation, an erase operation, and the like.

The address resister 12 holds an address information ADD received by the semiconductor memory device 1 from the memory controller 2. The address information ADD includes, for example, a block address BAd, a page address PAd, and a column address CAd. For example, the block addresses BAd, the page address PAd, and the column address CAd are used to select the block BLK, the word line WL, and the bit line BL, respectively.

The sequencer 13 controls the overall operation of the semiconductor memory device 1. For example, the sequencer 13 controls the driver module 14, the row decoder module 15, the sense amplifier module 16, and the like, based on the command CMD held in the command register 11, and executes a read operation, a write operation, an erase operation, and the like.

The driver module 14 generates a voltage used for the read operation, the write operation, the erase operation, and the like, and supplies the voltage to the row decoder module 15. The driver module 14 applies the generated voltage to a signal line corresponding to the selected word line WL based on the page address PAd held in the address resister 12.

The row decoder module 15 selects one block BLK in the memory cell array 10 based on the block address BAd held in the address resister 12. The row decoder module 15 then transfers, for example, the voltage applied to the signal line connected to the selected word line WL to the selected word line WL in the selected block BLK.

In the writing operation, the sense amplifier module 16 applies a voltage determined in accordance with the write data DAT received from the memory controller 2 to each bit line BL. Moreover, in the read operation, the sense amplifier module 16 determines data stored in the memory cell transistors MT based on the voltage of the bit line BL, and transfers the determination result to the memory controller 2 as the read data DAT.

The semiconductor memory device 1 and the memory controller 2 described above may form a single semiconductor memory device in combination with them. Examples of such a semiconductor memory device may include a memory card such as an SD™ card, an SSD (solid state drive), and the like.

[1-1-2] Circuit Configuration of Memory Cell Array 10

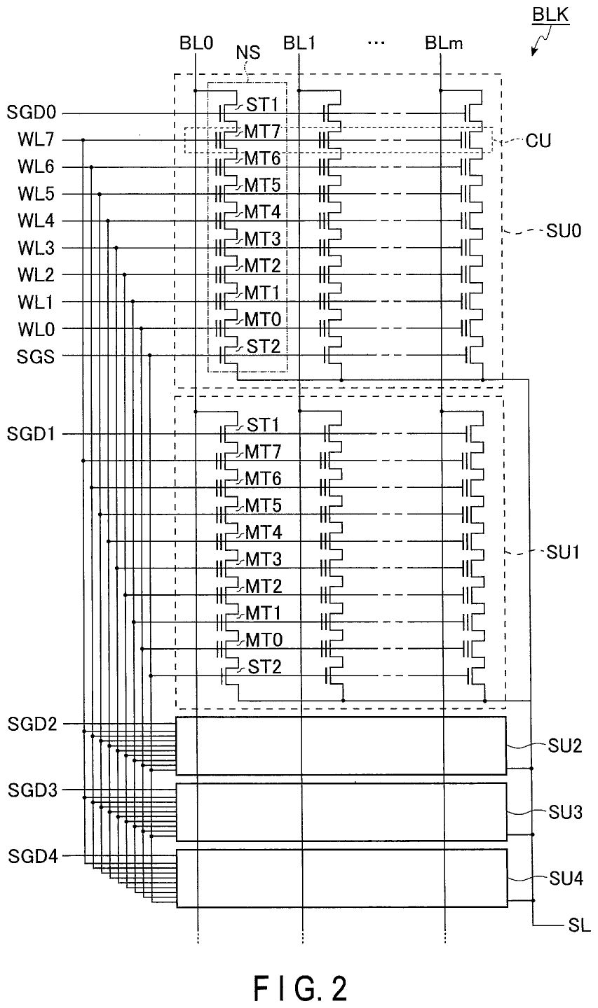

FIG. 2 is a circuit diagram showing an example of the circuit configuration of the memory cell array 10 included in the semiconductor memory device 1 according to the first embodiment. FIG. 2 shows one block BLK that is extracted from the blocks BLK included in the memory cell array 10. For example, each of the other blocks BLK includes the elements and the connections shown in FIG. 2. For example, the number of the blocks BLK in the memory cell array 10, and the number of string units SU in a single block BLK can be set to any numbers. The following description is based on an example in which a single block BLK includes five string units SU0-SU4.

Each string unit SU is a set of a plurality of NAND strings NS associated with bit lines BL0 to BLm (m is an integer of 1 or more). Each NAND string NS includes a plurality of memory cell transistors, such as memory cell transistors MT0 to MT7, and select transistors ST1 and ST2. The following description is based on an example in which each NAND string NS includes eight memory cell transistors MT0 to MT7.

Each memory cell transistor MT includes a control gate and a charge storage layer, and holds data in a non-volatile way. Each of the select transistors ST1 and ST2 is used for selecting the string units SU during various operations.

In each NAND string NS, the memory cell transistors MT0 to MT7 are connected in series. A drain of the select transistor ST1 is connected to an associated bit line BL. A source of the select transistor ST1 is connected to one end of a set of the memory cell transistors MT0 to MT7. The other end of the memory cell transistors MT0 to MT7 is connected to a drain of the select transistor ST2. A source of the select transistor ST2 is connected to a source line SL.

In the same block BLK, the control gates of the memory cell transistors MT0 to MT7 are connected to word lines WL0 to WL7, respectively. Respective gates of the select transistors ST1 in the string units SU0 to SU4 are connected to select gate lines SGD0 to SGD4, respectively. A plurality of gates of the select transistor ST2 is connected to a select gate line SGS.

A column address is assigned to each of the bit lines BL0 to BLm. The respective bit lines BL are shared by certain NAND strings NS of the blocks BLK. Each of the word lines WL0 to WL7 are provided for each block BLK. The source line SL is shared, for example, among the blocks BLK.

The sets of the memory cell transistors MT connected to common word lines WL in a single string unit SU is referred to as a cell unit CU, for example. For example, the storage capacity of the cell unit CU including the memory cell transistors MT, each storing 1-bit data, is defined as “1 page data”. The cell unit CU may have a storage capacity of two page data or more depending on the number of bits of data stored in the memory cell transistors MT.

Note that the circuit configuration of the memory cell array 10 included in the semiconductor memory device 1 according to the first embodiment is not limited to the above-described configuration. For example, the number of the memory cell transistors MT and the number of the select transistors ST1 and ST2 included in each NAND string NS may be designed to be any number.

[1-1-3] Structure of Memory Cell Array 10

Hereinafter, an example of the structure of the memory cell array 10 included in the semiconductor memory device 1 according to the first embodiment will be described. In the following description, a rectangular Cartesian coordinate system including an X axis, a Y axis, and a Z axis is used. In the following description, the description “lower” and its derivatives and related words refer to smaller positions on the Z axis of the coordinate, and the description “upper” and its derivatives and related words refer to larger positions on the Z axis of the coordinate. Hatching is appropriately added to a plan view for convenience of easier viewing of the drawings. The hatching added to the plan view is not necessarily related to the material or property of components to which the hatching is added. In a cross-sectional view, components such as insulating layers (interlayer insulating films), interconnects, contacts, and the like are appropriately omitted for convenience of easier viewing of the drawings. Further, the configuration shown in each drawing is appropriately simplified.

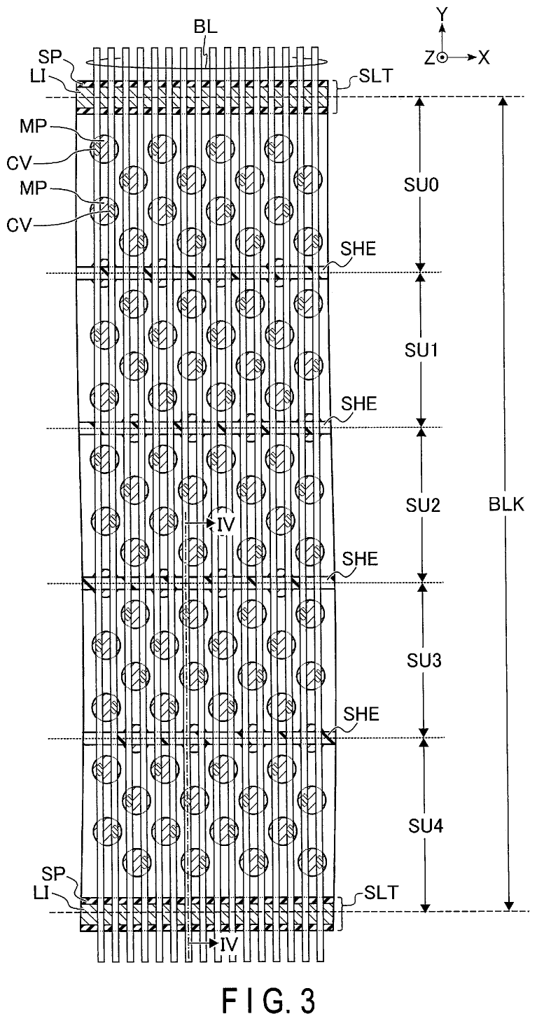

FIG. 3 is a plan view showing an example of the plan layout of the memory cell array 10 included in the semiconductor memory device 1 according to the first embodiment. In FIG. 3, a region including a single block BLK (i.e., the string units SU0 to SU4) is extracted and shown. As shown in FIG. 3, the memory cell array 10 includes a plurality of memory pillars MP, a plurality of contacts CV, a plurality of members SLT and SHE, and a plurality of bit lines BL.

The members SLT each extend along the X axis, and are aligned along the Y axis. Each member SLT includes contacts LI and spacers SP. Each contact LI is a conductor extending in the XZ plane. Each spacer SP is an insulator provided on the side surface of each contact LI. In other words, the contact. LI is surrounded by the spacer SP in XY plane view. Each member SLT divides adjacent stack interconnects (described later) via this member SLT.

The members SHE each extend along the X axis, and are aligned along the Y axis. In this example, four members SHE are arranged between the adjacent members SLT, respectively. Each member SHE has, for example, a structure in which an insulator is embedded. Each member SHE divides adjacent select gate lines SGD (described later) via this member SHE.

In the plan layout of the memory cell array 10 described above, the region separated by the members SLT functions as a single block BLK. In addition, each region separated by the member SLT and the member SHE and each region separated by the member SHE and the member SHE function as single string units SU, respectively. Specifically, for example, each member SHE is arranged between the string units SU0 and SU1 adjacent to each other in the Y direction, between the string units SU1 and SU2, between the string units SU2 and SU3, and between the string units SU3 and SU4, respectively. In the memory cell array 10, for example, a layout similar to the layout shown in FIG. 3 is repeatedly arranged in the Y direction.

Note that the semiconductor memory device 1 according to the first embodiment is not limited to the above described layout. For example, the number of the members SHE arranged between the adjacent members SLT may be designed to be any number. The number of the string units SU formed between the adjacent members SLT may be changed based on the number of the members SHE arranged between the adjacent members SLT.

The memory pillars MP are arranged in a staggered pattern, for example, in 24 rows in the region between two adjacent members SLT. For example, counting from the upper side (+Y side) of the drawing, a single member SHE overlaps the memory pillars MP in the 5th column, the memory pillars MP in the 10th column, the memory pillars MP in the 15th column, and the memory pillars MP in the 20th column. Note that the number and arrangement of the memory pillars MP between the adjacent members SLT are not limited to this, and may be changed as appropriate. The memory pillars MP each function as a single NAND string NS, for example.

The bit lines BL each extend along the Y axis, and are aligned along the X axis. In each string unit SU, each bit line BL is arranged so as to overlap at least one memory pillar MP. An example of FIG. 3 shows a case in which two bit lines BL are arranged to overlap a single memory pillar MP. Between one of the bit lines BL overlapping the memory pillars MP and the memory pillars MP, the contacts CV are provided. Each memory pillar MP is electrically connected to one bit line BL via the contact CV. One contact CV is connected to one bit line BL in each of the regions separated by the members SLT or the members SHE.

For example, each contact CV between the memory pillar MP in contact with the member SHE and the bit line BL is omitted. In other words, the contacts CV between the memory pillars MP in contact with two different select gate lines SGD and the bit line BL are omitted. The number and arrangement of the memory pillars MP and the number and arrangement of the members SHE, and the like between the adjacent members SLT are not limited to the configuration described with reference to FIG. 3, and may be changed as appropriate. The number of the bit lines BL overlapping the respective memory pillars MP may be designed to be any number.

[1-1-4] Cross-Sectional Structure of Memory Cell Array 10

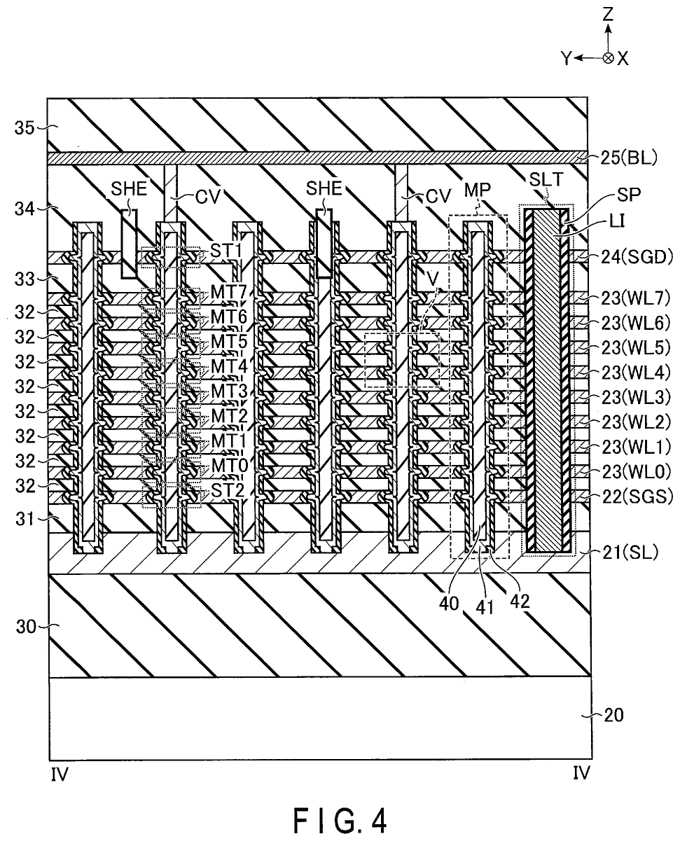

FIG. 4 is a cross-sectional view taken along line IV-IV of FIG. 3, and shows an example of the cross-sectional structure in the semiconductor memory device 1 according to the first embodiment. As shown in FIG. 4, the semiconductor memory device 1 further includes, for example, a semiconductor substrate 20, conductive layers 21 to 25, and insulating layers 30 to 34.

The insulating layer 30 is provided on the semiconductor substrate 20. The insulating layer 30 contains, for example, silicon oxide (SiO₂). Although the illustration is partially omitted, a circuit region is provided in a part of the semiconductor substrate 20 and in the insulating layer 30, and memory cell array 10 is provided above the insulating layer 30. In the circuit region, for example, a circuit used for the row decoder module 15 or the sense amplifier module 16 is formed.

Above the insulating layer 30, the conductive layer 21 is provided. The conductive layer 21 is formed in a plate shape extending along the XY plane, for example, and is used as the source line SL. The conductive layer 21 contains, for example, phosphorus (P)-doped silicon (Si), a metallic material, and the like.

An insulating layer 31 is provided on the conductive layer 21. The insulating layer 31 contains, for example, silicon oxide. The conductive layer 22 is provided on the insulating layer 31. The conductive layer 22 is formed in a plate shape extending along the XY plane, for example. The conductive layer 22 is used as the select gate line SGS. The conductive layer 22 contains, for example, tungsten (W) or molybdenum (Mo).

Above the conductive layer 22, the insulating layers 32 and the conductive layers 23 are alternately stacked. The conductive layer 23 is formed in a plate shape extending along the XY plane, for example. The stacked conductive layers 23 are used as word lines WL0 to WL7 in order from the semiconductor substrate 20 side. The conductive layer 23 contains, for example, tungsten or molybdenum. The insulating layer 32 contains, for example, silicon oxide.

Above the conductive layer 23 that is the uppermost layer, the insulating layer 33 is provided. The insulating layer 33 contains, for example, silicon oxide. The conductive layer 24 is provided on the insulating layer 33. The conductive layer 24 is formed, for example, in a plate shape extending along the XY plane. The conductive layer 24 is used as the select gate line SGD. The conductive layer 24 contains, for example, tungsten or molybdenum.

The insulating layer 34 is provided on the conductive layer 24. The insulating layer 34 contains, for example, silicon oxide. The conductive layer 25 is provided on the insulating layer 34. The conductive layer 25 is formed in a line shape extending in the Y direction, for example. The conductive layer 25 is used as the bit line BL. In a not-shown region, the conductive layers 25 are arranged along the X direction. The conductive layer 25 contains, for example, copper (Cu).

The insulating layer 35 is provided on the conductive layer 25. The insulating layer 35 contains, for example, silicon oxide. The insulating layer 35 includes interconnections that connect the memory cell array 10 with the row decoder module 15 and the sense amplifier module 16, and others.

The memory pillars MP extends along the Z direction, and extends through the insulating layers 31 to 33 and the conductive layers 22 to 24. The respective upper ends of the memory pillars MP are included in the insulating layer 34. The respective bottoms of the memory pillars MP are included in the conductive layer 21. The shape of the memory pillar MP in intersecting parts between the conductive layers 22 to 24 and the memory pillar MP is different from the shape of the memory pillar MP in the other parts. For example, in the intersection parts between the conductive layers 22 to 24 and the memory pillar MP, the diameter of the memory pillar MP is larger than the diameter of the memory pillar MP in the other layers. The details will be described later with reference to FIG.

The memory pillars MP each include, for example, a core member 40, a semiconductor layer 41, and a stacked film 42. The core member 40 extends along the Z direction, and is provided in the central part of the memory pillar MP. For example, the upper end of the core member 40 is included in a layer above the layer in which the conductive layer 24 is provided. The lower end of the core member 40 reaches the conductive layer 21. The core member 40 contains an insulator of silicon oxide, or the like, for example.

The semiconductor layer 41 covers, for example, the circumference of the core member 40. For example, the bottom surface of the semiconductor layer 41 is in contact with the conductive layer 21. The semiconductor layer 41 contains, for example, silicon. The semiconductor memory device 1 according to the first embodiment may have a structure in which the core member 40 is not provided and the semiconductor layer 41 is embedded up to the central part thereof.

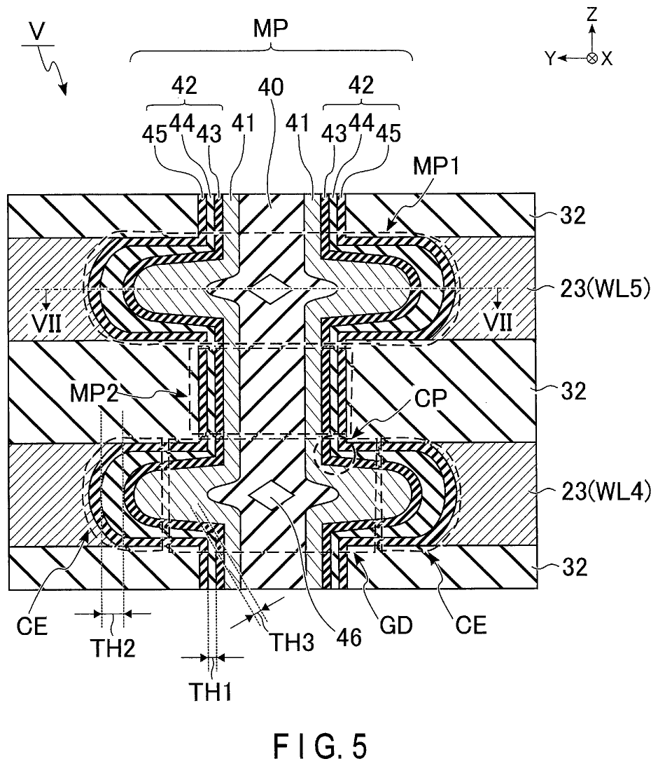

The stacked film 42 covers the side surface and the bottom surface of the semiconductor layer 41 except for a part where the semiconductor layer 41 and the conductive layer 21 are in contact with each other. The details of the stacked film 42 will be described later with reference to FIG. 5.

In the structure of the memory pillar MP described above, a part where the memory pillar MP and the conductive layer 22 intersect each other functions as the select transistor ST2. A part where the memory pillar MP and one conductive layer 23 intersect each other functions as one memory cell transistor MT. A part where the memory pillar MP and the conductive layer 24 intersect each other functions as the select transistor ST1.

The contact CV in a columnar shape is provided on the upper surface of the semiconductor layer 41 in the memory pillar MP. In the illustrated area, the contacts CV connected to two of the six memory pillars MP are illustrated. As for the memory pillars MP which do not overlap the members SHE and to which no contacts CV are connected in this illustrated area, other contacts CV are connected to these pillars MP in a not-illustrated area.

One conductive layer 25, that is, one bit line BL is in contact with the upper surface of the contacts CV. One contact CV is connected to one conductive layer 25 in each of the spaces separated by the members SLT and SHE. That is, a memory pillar MP provided between the adjacent members SLT and SHE, and a memory pillar MP provided between two adjacent members SHE are electrically connected to each of the conductive layers 25.

The member SLT has a part provided along the XZ plane, for example, and divides the conductive layers 22 to 24 and the insulating layers in the Y direction. The contact LI in the member SLT is provided along the member SLT. The upper end of the contact LI is in contact with the insulating layer 34. The lower end of the contact LI is in contact with the conductive layer 21. The contact LI is used as a part of source line SL, for example. The spacer SP is provided at least between the contact LI and the conductive layers 22 to 24. The contact LI and the conductive layers 22 to 24 are separated and isolated from each other by the spacer SP. The member SLT may have a structure in which the contact LI is not provided and the insulator is embedded through the entire member SLT.

The members SHE are provided, for example, along the XZ plane, and divide at least the conductive layer 24 in the Y direction. The upper end of each member SHE is in contact with the insulating layer 34. The lower end of each member SHE is in contact with the insulating layer 33. The member SHE contains, for example, an insulator of silicon oxide or the like. The upper ends of the members SHE and the upper ends of the members SLT may or may not be aligned with each other. Further, the upper ends of the members SHE and the upper ends of the memory pillars MP may or may not be aligned with each other.

FIG. 5 is an enlarged view of a region V in FIG. 4, and shows an example of the cross-sectional structure of each memory pillar MP in the semiconductor memory device 1 according to the embodiment.

The memory pillar MP includes a plurality of pillar first regions MP1 and a plurality of pillar second regions MP2. Each pillar first region MP1 is a part of the memory pillar MP that intersects the conductive layers 22, 23, and 24.

The pillar second regions MP2 are parts of the memory pillar MP other than the pillar first regions MP1. In other words, the pillar second regions MP2 are parts of the memory pillar MP that intersect the insulating layer 31, 32, 33, or 34. The insulating layers 31, 32, 33, and 34 may be referred to as interlayer insulating films.

FIG. 5 shows a part of the memory pillar MP, and shows the structure of the conductive layers 23 and the structure of the region in the memory pillar MP that intersects the conductive layers 23. Although not shown in the drawing, the region in the memory pillar MP that intersects the conductive layers 22 or 24 may or may not have the same structure as that of the region that intersects the conductive layers 23 as described below. Hereinafter, regarding the shape of the pillar first region MP1, the part intersecting the conductive layers 23 will be mainly described.

The memory pillar MP has parts protruding in the XY direction while extending along the Z direction. The parts protruding in the XY direction are the pillar first regions MP1. That is, the diameter of each pillar first region MP1 is larger than the diameter of each pillar second region MP2.

The pillar first region MP1 includes a cell region CE and a guard region GD. The cell region CE includes a part of the pillar first region MP1 in contact with the conductive layer 22, 23, or 24. The cell region CE extends from the upper surface to the lower surface of the insulating layer 32 (interlayer insulating film). The guard region GD is a region that is closer to the central part of the memory pillar MP than the cell region CE is.

Specifically, in the cell region CE in contact with the conductive layer 23, the memory cell transistor MT mainly has a function of storing electric charge in the insulating film 44 described later. This is because the cell region CE is located closer to the conductive layer 23 as an electrode, and can store electric charge in accordance with the applied voltage. The region having this function may be referred to as the cell region CE.

The guard regions GD are parts of the pillar first region MP1 other than the cell regions CE. For example, the insulating film 44 in each guard region GD, which is located apart from the conductive layer 23, is difficult to store electric charge. This is because the insulating film is located farther from the conductive layers 22 to 24 as an electrode; therefore, this insulating film is difficult to store electric charge in accordance with the applied voltage. The insulating film 44 in the guard region GD has a function of suppressing leakage of the electric charge charged in the insulating film 44 in the cell region CE.

In other words, the cell region CE located closer to the conductive layer 23 as an electrode functions as the memory cell transistor MT, while the guard region GD located farther therefrom has a part that does not function as the memory cell transistor MT. The details of the cell region CE and the guard region GD will be described later.

The stacked film 42 includes, for example, a tunnel insulating film 43, an insulating film 44, and a block insulating film 45. As described above, the core member 40 extends along the Z direction, and is provided in the central part of the memory pillar MP. The pillar first region MP1 may include voids 46 in a part of the central region of the core member 40. The core member 40 surrounds the surface of each void 46. In the case in which the memory pillar MP includes no void 46, the region of the voids 46 is filled, for example, with the core member 40. The case in which no void 46 is provided will be described later in a modified example. The semiconductor layer 41 covers, for example, the circumference of the core member 40. The tunnel insulating film 43 is provided on the side surface of the semiconductor layer 41. The insulating film 44 is provided on the side surface of the tunnel insulating film 43. Although the details will be described later, the insulating film 44 is used as a charge storage layer of the memory cell transistor MT. The block insulating film 45 is provided on the side surface of the insulating film 44.

In addition, the semiconductor layer 41, the tunnel insulating film 43, the insulating film 44, and the block insulating film 45 in the cell region CE, and the semiconductor layer 41, the tunnel insulating film 43, the insulating film 44, and the block insulating film 45 in the pillar second region MP2 are not adjacent to each other along the Z axis.

As the tunnel insulating film 43, an insulating material of silicon oxide, silicon nitride, a silicon oxynitride film, or the like is used. The block insulating film 45 contains, for example, silicon oxide. The insulating film 44 contains, for example, silicon nitride.

The thickness of each layer in the pillar second region MP2 will be described. In the pillar second region MP2, the thicknesses of the core member 40, the semiconductor layer 41, the tunnel insulating film 43, the insulating film 44, and the block insulating film 45 do not depend on the Z axis. That is, the thicknesses of the core member 40, the semiconductor layer 41, the tunnel insulating film 43, the insulating film 44, and the block insulating film 45 are substantially constant regardless of whether that is in a region at or near the middle of the pillar second region MP2 along the Z axis or in a region at or near the end of the pillar second region MP2 along the Z axis. The region at or near the middle of the pillar second region MP2 along the Z axis is a region apart from the interlayer insulating film such as the insulating layer 32. The region at or near the middle of the pillar second region. MP2 along the Z axis may be referred to hereinafter as a “middle of the pillar second region MP2” for simplicity of the description. The regions at or near the respective ends of the pillar second region MP2 along the Z axis are, for example, regions each closer to the corresponding interlayer insulating film such as the insulating layer 32. The regions at or near the ends of the pillar second region MP2 along the Z axis may each be referred to hereinafter as an “end of the pillar second region MP2”.

Similarly, the region at or near the middle of the pillar first region MP1 along the Z axis may be referred to hereinafter as a “middle of the pillar first region MP1”. The regions at or near the ends of the pillar first region MP1 along the Z axis may each be referred to hereinafter as an “end of the pillar first region MP1”.

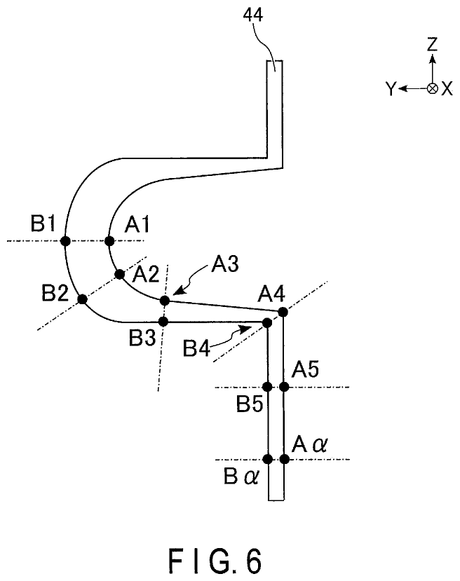

Here, a “thickness” with respect to a point A1 on one plane of a certain first layer having two opposing planes is a distance between the point A1 and a point B1 at which a normal line starting from the point A1 intersects the other plane of this first layer. Describing with reference to FIG. 6 and using the insulating film 44 as an example, for example, the “thickness” with respect to the point A1 is a distance between the point A1 and the point B1, which is an intersection point between the normal line starting from the point A1 and a boundary plane of the insulating film 44. Taking a as a positive integer, the same applies to a “thickness” with respect to Aa; and for example, a “thickness” with respect to the point Aa is a distance between the point Aa and a Ba point. For example, the thickness in the middle of the pillar first region MP1 of the insulating film 44 is a distance between a certain first point on one plane in the middle of the pillar first region MP1 of the insulating film 44 and a second point that intersects a normal line of the first point on the other plane in the middle of the pillar first region MP1 of the insulating film 44.

Next, returning to FIG. 5, the thickness of each layer in the pillar first region MP1 will be described. As shown in FIG. 5, in the pillar first region MP1, the thicknesses of the core member 40, the tunnel insulating film 43, and the block insulating film 45 do not depend on the Z axis. In the pillar first region MP1, the thicknesses of the semiconductor layer 41 and the insulating film 44 depend on the Z axis.

Specifically, the core member 40 is provided so as to have substantially the same thickness regardless of whether that is in the middle of the pillar first region MP1 or in the end of the pillar first region MP1. Here, the core member 40 covers the circumference of each void 46 substantially uniformly. That is, the diameter of the core member 40 is larger in the region having the void 46 than that in the region having no void 46 by the size of the void 46.

The semiconductor layer 41 is provided so as to be thicker in the middle of the pillar first region MP1 than that in the end of the pillar first region MP1. In other words, the semiconductor layer 41 is thicker in the middle of the pillar first region MP1 and thinner in the end of the pillar first region MP1, and covers the circumference of the core member 40.

The tunnel insulating film 43 is provided so as to have substantially the same thickness regardless of whether that is in the middle of the pillar first region MP1 or in the end of the pillar first region MP1. In other words, the tunnel insulating film 43 covers the circumference of the semiconductor layer 41 substantially uniformly both in the middle of the pillar first region MP1 and in the end of the pillar first region MP1.

The insulating film 44 is provided so as to be thicker in the middle of the pillar first region MP1 than that in the end of the pillar first region MP1. In other words, the insulating film 44 is thicker in the middle of the pillar first region MP1 and thinner in the end of the pillar first region MP1, and covers the circumference of the tunnel insulating film 43.

The insulating film 44 has a part provided so as to be the thinnest in the guard region GD, and the thickness of this part may be referred to as a charge storage layer thickness TH3. For example, the part where the insulating film 44 is provided so as to be the thinnest may include a part having an angle that is an intersection point between a part where the insulating film 44 extends along the Z axis and a part where the insulating film 44 extends along the XY plane (may be referred to hereinafter as a corner part CP). The corner part CP of the guard region GD includes a boundary region between the insulating layer 32 and the conductive layer 23 in the guard region GD. As will be described later in the manufacturing method, the insulating film 44 in the corner part CP is easily provided to be thin.

The insulating film 44 has a part provided so as to be the thickest in the cell region CE, and the thickness of this part may be referred to as a charge storage layer thickness TH2. The insulating film 44 is provided so as to have substantially the same thickness in the pillar second region MP2, and this thickness may be referred to as a charge storage layer thickness TH1. The thickness decreases in the order of the charge storage layer thickness TH2, the charge storage layer thickness TH1, and the charge storage layer thickness TH3. For example, the charge storage layer thickness TH2 may be larger than the charge storage layer thickness TH3 by 2 nm or more. Further, for example, the charge storage layer thickness TH2 may be larger than the charge storage layer thickness TH1 by 2 nm or more.

For example, when the insulating film 44 located in the layer in which the conductive layer 23 is located is referred to as a first part, and the insulating film 44 located in the layer in which the insulating layer 32 is located is referred to as a second part, respectively, the insulating film 44 has a portion having a thicker thickness in the first part than that in the second part. In other words, for example, in the insulating film 44, the first part located in the layer in which the conductive layer 23 is located has a portion whose thickness is thicker than the second part located in the layer in which the insulating layer 32 is located.

For example, in the insulating film 44 in at least one set of the guard region GD, the pillar second region MP2, and the cell region CE, a difference between the maximum thickness and the minimum thickness is 2 nm or more. For example, in the insulating film 44 in at least one set of the guard region GD and the cell region CE, a difference between the maximum thickness and the minimum thickness is 2 nm or more. For example, in the insulating film 44 in at least one set of the pillar second region MP2 and the cell region CE, a difference between the maximum thickness and the minimum thickness may be 2 nm or more.

The block insulating film 45 is provided so as to have substantially the same thickness regardless of whether that is in the middle of the pillar first region MP1 or in the end of the pillar first region MP1. In other words, the block insulating film 45 covers the circumference of the insulating film 44 substantially uniformly, both in the middle of the pillar first region MP1 and in the end of the pillar first region MP1.

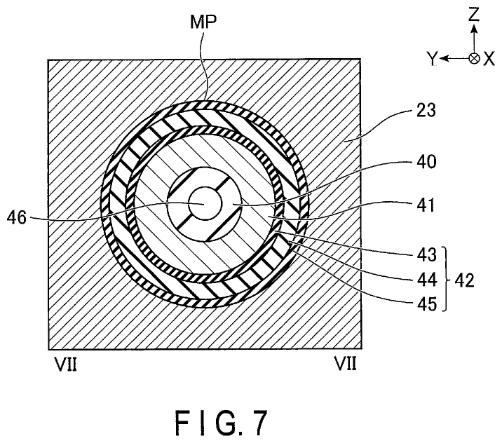

FIG. 7 is a cross-sectional view taken along line VII-VII of FIG. 5, and shows an example of the cross-sectional structure of the memory pillar MP in the semiconductor memory device 1 according to the first embodiment. Specifically, FIG. 7 shows the cross-sectional structure of the memory pillar MP in a layer that is parallel to the surface of the semiconductor substrate 20 and includes the conductive layer 23.

In the cross section including the conductive layer 23, the memory pillar MP may have a void 46 that is located in the central part. The core member 40 surrounds the side surface of the void 46. The semiconductor layer 41 surrounds the side surface of the core member 40. The tunnel insulating film 43 surrounds the side surface of the semiconductor layer 41. The insulating film 44 surrounds the side surface of the tunnel insulating film 43. The block insulating film 45 surrounds the side surface of the insulating film 44. The conductive layer 23 surrounds the side surface of the block insulating film 45. The tunnel insulating film 43 and the block insulating film 45 each contain, for example, silicon oxide. The insulating film 44 contains, for example, silicon nitride.

The structure of the conductive layer 22 and the memory pillar MP in the layer parallel to the surface of the semiconductor substrate 20 and including the conductive layer 22, and the structure of the conductive layer 24 and the memory pillar MP in the layer parallel to the surface of the semiconductor substrate 20 and including the conductive layer 24 may be the same as the structure of the conductive layer 23 and the memory pillar MP in the layer parallel to the surface of the semiconductor substrate 20 and including the conductive layer 23.

In the above described memory pillar MP, the semiconductor layer 41 is used as respective channels (current paths) of the memory cell transistors MT0 to MT7 and the select transistors ST1 and ST2. The semiconductor memory device 1 can pass a current via the memory pillars MP between the bit lines EL and the contacts LI by turning on the memory cell transistors MT0 to MT7 and the select transistors ST1 and ST2. This allows each of the memory pillars MP to function as a single NAND string NS.

[2] Manufacturing Method of Semiconductor Memory Device 1

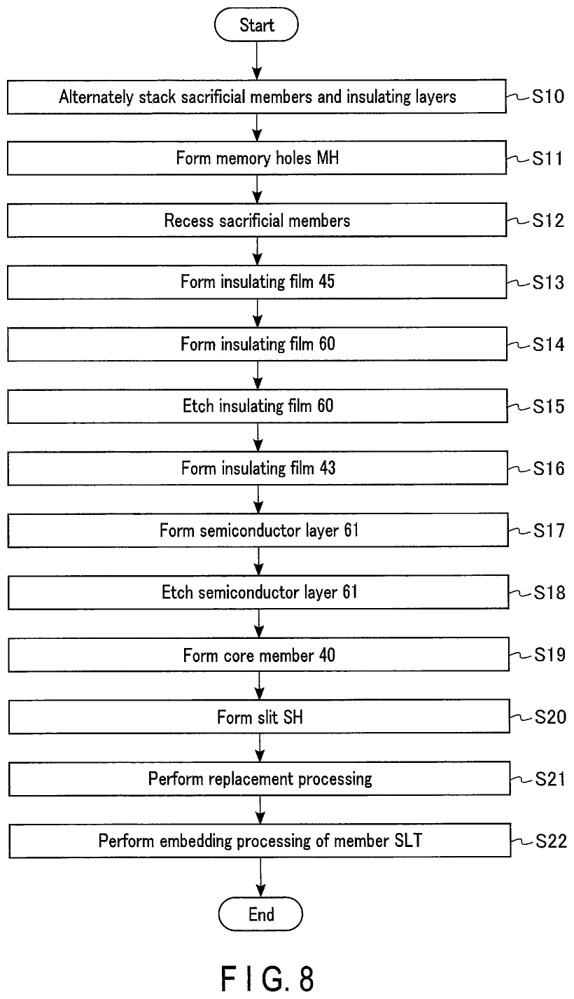

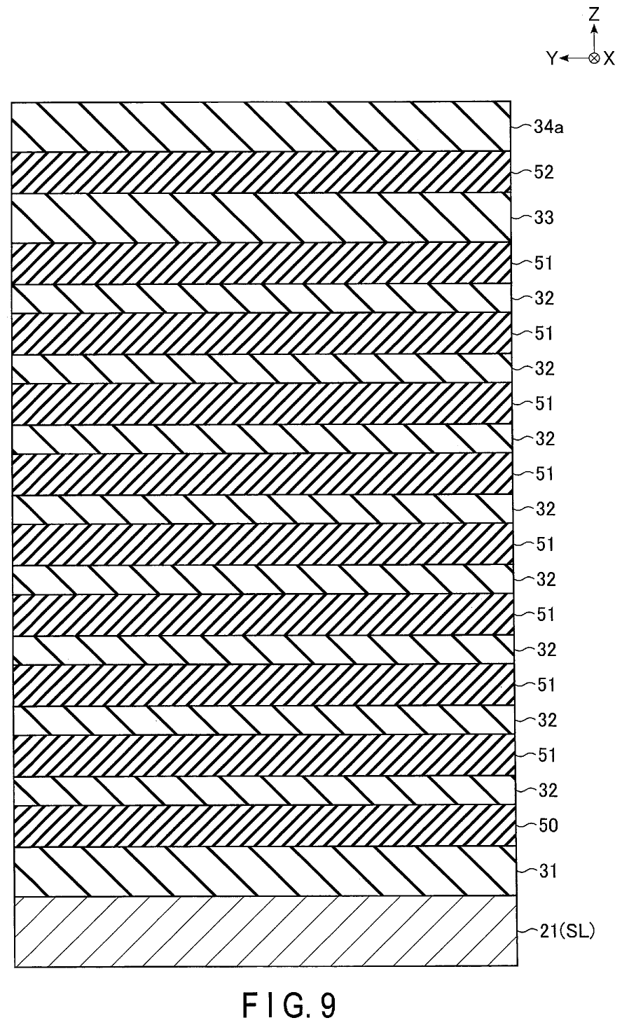

FIG. 8 is a flowchart showing an example of the manufacturing method of the semiconductor memory device 1 according to the embodiment. Each of FIG. 9 to FIG. 21 is an example of the cross-sectional structure in the middle of manufacturing the semiconductor memory device 1 according to the embodiment. Each of FIG. 9 to FIG. 21 shows an area including a part of the region shown in FIG. 5. Hereinafter, an example of the manufacturing steps regarding formation of a stacked interconnect structure in the memory cell array 10 of the semiconductor memory device 1 according to the embodiment will be described with reference to FIG. 8 as appropriate. As shown in FIG. 8, in the manufacturing method of the semiconductor memory device 1 according to the embodiment, for example, the processing of steps S10 to S17 is sequentially executed.

In the processing of step S10, the sacrificial members and the insulating layers are alternately stacked as shown in FIG. 9. First, the insulating layer 30, the conductive layer 21, the insulating layer 31, and the sacrificial member 50 are formed in order on the semiconductor substrate 20. The insulating layers 32 and the sacrificial members 51 are alternately stacked on the sacrificial member 50. On the sacrificial member 51 that is the uppermost layer, the insulating layer 33 and the sacrificial member 52 are formed in order. An insulating layer 34a is formed on the sacrificial member 52.

The sacrificial member 50 is formed in a region where the conductive layer 22 functioning as the select gate line SGS is to be formed. The sacrificial member 51 is formed in regions where the conductive layers 23 functioning as the word lines WL are to be formed. For example, the number of layers where the sacrificial members 51 are formed is equal to the number of the word lines WL. The sacrificial member 52 is formed in a region where the conductive layer 24 functioning as the select gate line SGD is to be formed. Each of the insulating layers 30 to 34a contains, for example, silicon oxide. Each of the sacrificial members 50 to 52 is, for example, silicon nitride.

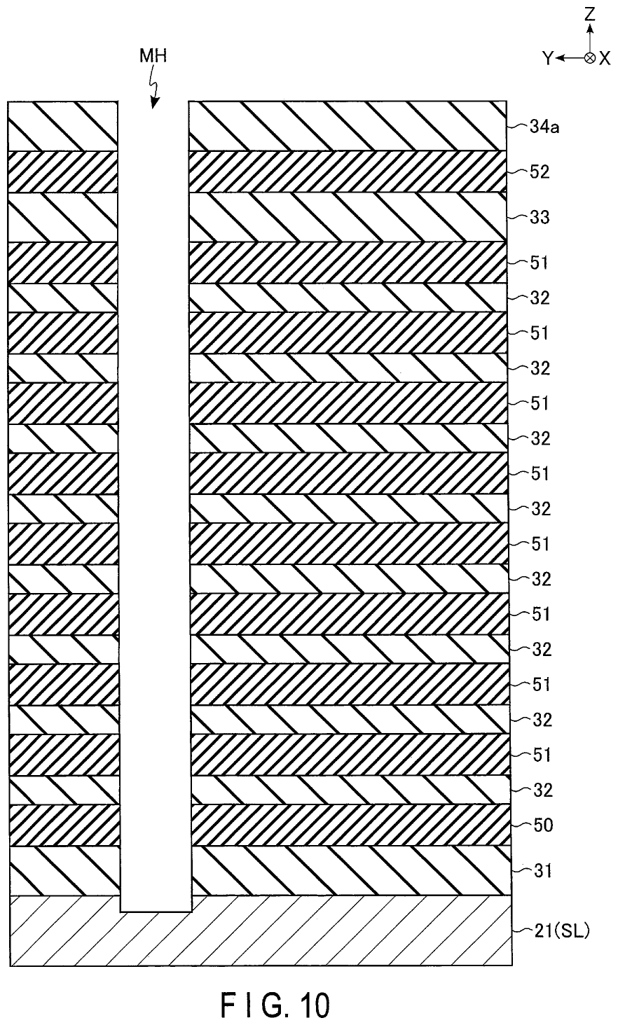

In the processing of step S11, the memory holes MH are formed as shown in FIG. 10. Specifically, first, a mask having openings in regions where the memory pillars MP are to be formed is formed by photolithography or the like. The memory holes MH are formed by anisotropic etching using the mask thus formed. Each memory hole MH penetrates the insulating layers 31 to 34a and the sacrificial members 50 to 52, respectively. The bottoms of the memory holes MH reach, for example, the inside of the conductive layer 21.

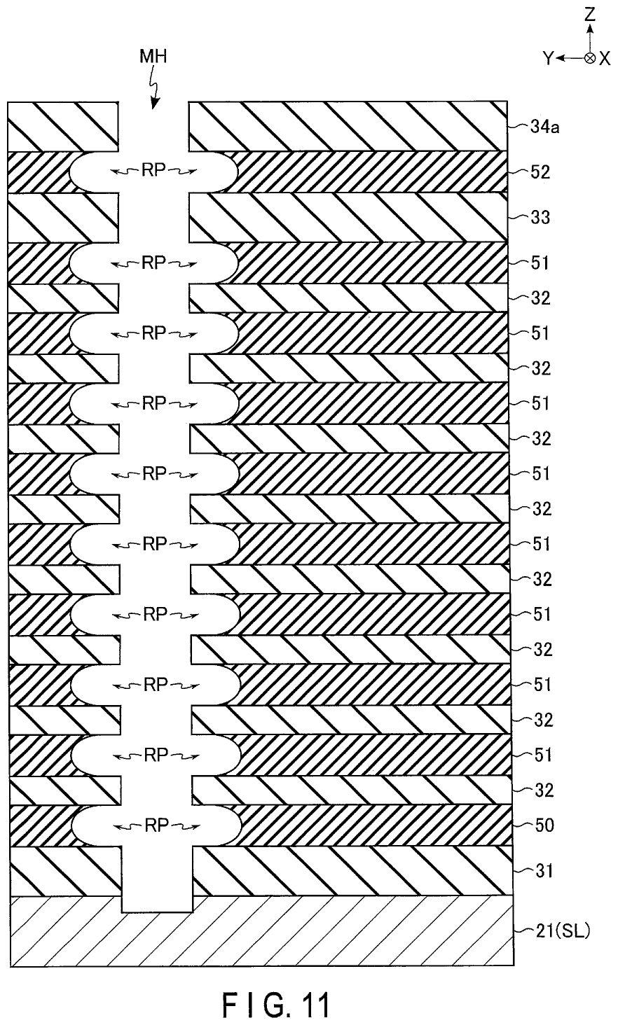

In the processing of step S12, as shown in FIG. 11, parts of the sacrificial members 50 to 52 are recessed. Specifically, wet-etching is performed via each memory hole MH to remove a part of each of the sacrificial members 50 to 52 exposed on the side surfaces of the memory hole MH. As a result, the side surface of the memory hole MH is processed into a shape in which the sacrificial members 50 to 52 are partially removed. The spaces created by partially removing the sacrificial members 50 to 52 in this step may be referred to hereinafter as spaces RP. Each of the spaces RP is a region where the cell region CE or the like is to be formed. Due to the formation of the spaces RP, the diameter of the memory hole MH is larger in the layers including the sacrificial members 50 to 52 than that in the other regions. The layers including the sacrificial members 50 to 52 in the memory hole MH are regions where the pillar first regions MP1 are to be formed.

The diameter of the memory hole MH in the layers including the sacrificial members 50 may be formed to be the largest at or near the middle thereof along the Z axis, and may be formed to be gradually smaller as the diameter comes closer to the interfaces with the upper and lower insulating layers (interlayer insulating films). That is, the diameter of the memory hole MH may be formed to be the largest in the central part of the region where the pillar first region MP1 is to be formed, and may be formed to be gradually smaller as the diameter comes closer to the end parts of the region where the pillar first region MP1 is to be formed.

For example, at this time, the shape of the memory hole MH in the ZY cross section has a curve in a protruding shape at or near the middle thereof along the Z axis in the layer including the sacrificial member 50. In other words, the diameter of the region where the pillar first region MP1 is to be formed is larger than the diameter of the region where the pillar second region MP2 is to be formed.

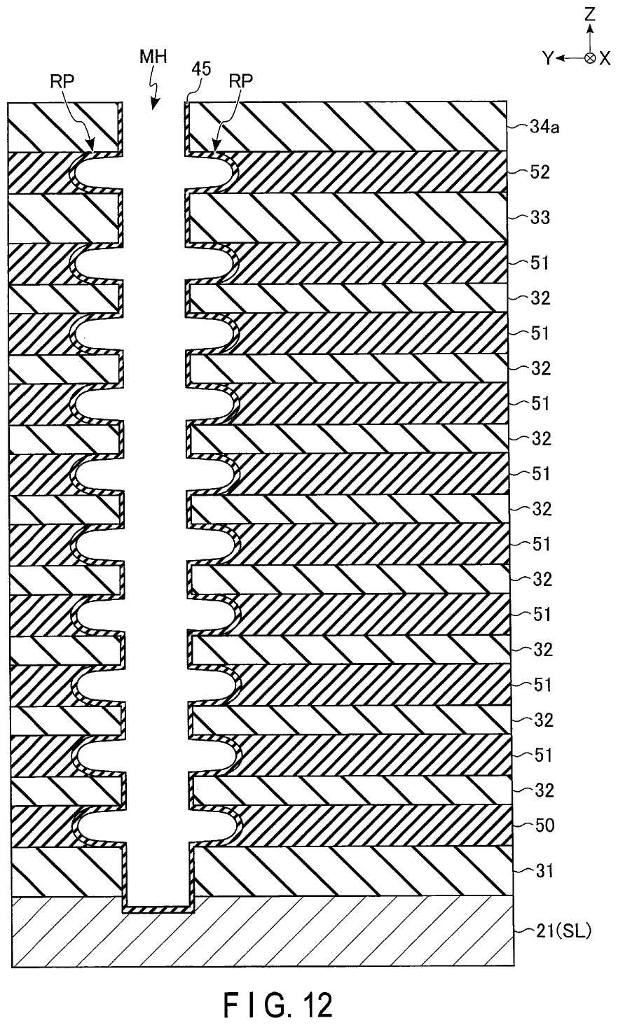

In the processing of step S13, the block insulating film 45 is formed as shown in FIG. 12. Specifically, the block insulating film 45 is formed on the surface and the bottom surface of the memory hole MH as well as the exposed surface in each space RP of the memory hole MH.

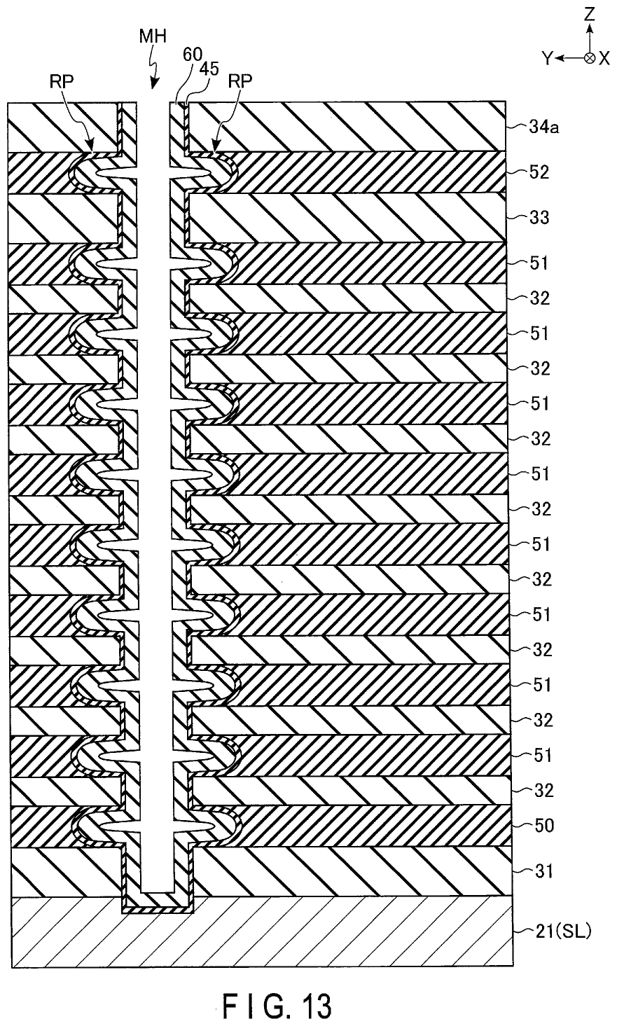

In the processing of step S14, the insulating film 60 is formed as shown in FIG. 13. Specifically, the insulating film 60 is formed on the surface of the block insulating film 45.

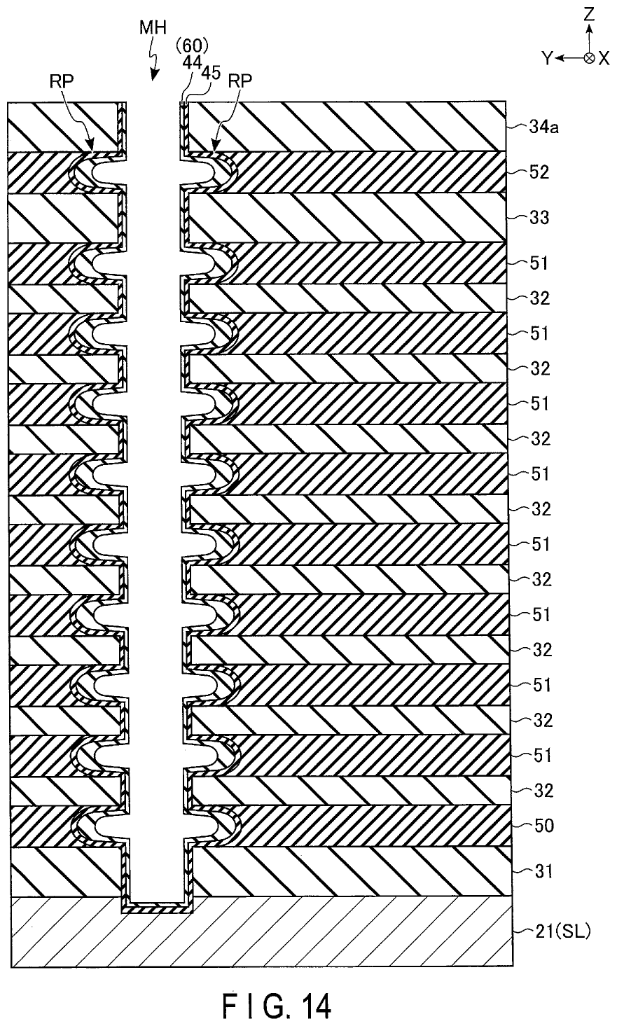

In the processing of step S15, the etching processing of the insulating film 60 is performed as shown in FIG. 14. Specifically, the wet-etching is performed via the memory hole MH to remove parts of the insulating film 60 exposed on the side surface of the memory hole MH. The insulating film 60 after being subjected to the etching processing is referred to as the insulating film 44. That is, the insulating film 60 is etched to be formed into the insulating film 44.

Specifically, a wet-etching solution reaches the surface of the insulating film 60 via the memory hole MH and the spaces RP. The wet-etching solution etches parts of the insulating film 60 that are exposed in the memory hole MH and in the spaces RP, respectively.

Here, in the wet-etching performed in the processing of step S15, the speed at which the etching proceeds in the parts each having a concave shape is slower than the speed at which the etching proceeds in the parts each having a planar shape. Similarly, the speed at which the etching proceeds in the parts each having a planar shape is slower than the speed at which the etching proceeds in the parts each having a protruding shape. In other words, the etching proceeds more slowly in the parts each having a large radius of curvature than in the parts each having a small radius of curvature. This is because, for example, the wet-etching solution more easily reaches the parts each having a protruding shape than the parts each having a concave shape.

Since the wet-etching solution is introduced from the memory hole MH, the parts of the insulating film 60 each having a concave shape in the memory hole MH are, for example, the cell regions CE. In other words, the cell regions CE correspond to the parts each having a concave shape in the memory hole MH.

Similarly, the parts of the insulating film 60 each having a protruding shape in the memory hole MH include, for example, the corner parts CP in the guard regions GD. In other words, the corner parts CP of the guard regions GD correspond to the parts each having a protruding shape in the memory hole MH.

Similarly, the parts of the insulating film 60 each hawing a planar shape in the memory hole MH include, for example, the pillar second regions MP2. In other words, the pillar second regions MP2 correspond to the parts each having a planar shape in the memory hole MH.

Accordingly, in the insulating film 60, the etching proceeds faster at or near the corner parts CP of the guard regions GD than in the pillar second regions MP2; and as a result, the insulating film 44 is formed to be thinner there. Similarly, in the insulating film 60, the etching proceeds faster in the pillar second regions MP2 than in the cell regions CE; and as a result, the insulating film 44 is formed to be thinner there. In other words, the insulating film 44 in the cell regions CE can be formed to be thicker than in the other parts, and the insulating film 44 at or near the corner parts CP in the guard regions GD can be formed to be thinner than in the other parts.

For example, in each cell region CE, the insulating film 44 becomes thicker as this comes closer to recess of the concave part. This is because the closer to the recess of the concave part, the more difficult the wet-etching solution introduced from the memory hole MH to reach. In other words, for example, in each cell region CE, the closer to the middle of the pillar first region MP1, the thicker the insulating film 44.

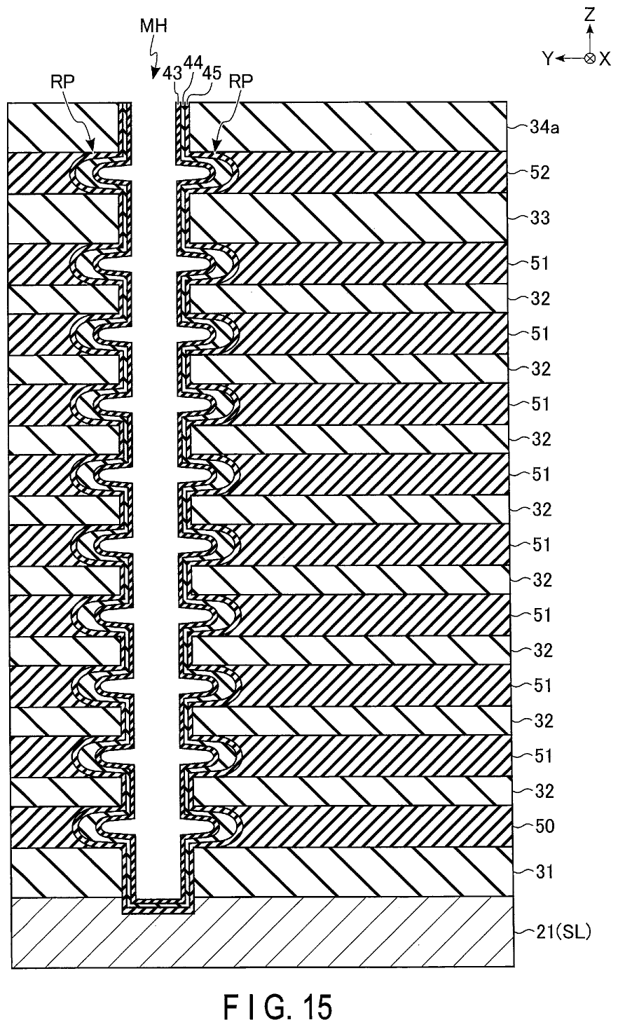

In the processing of step S15, the insulating film 60 of each pillar second region MP2 may be completely etched, and the insulating film 44 may be formed only in parts of the guard regions GD and in the cell regions CE. This structure will be described later in the second embodiment. In the processing of step S16, the tunnel insulating film 43 is formed as shown in FIG. 15. Specifically, the tunnel insulating film 43 is formed on the surface of the insulating film 60.

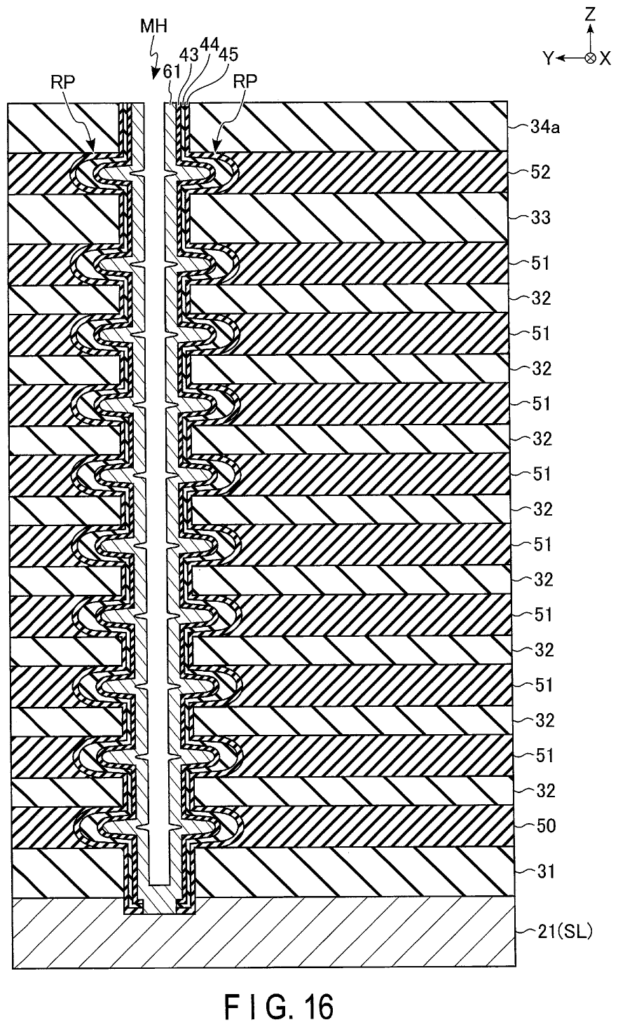

In the processing of step S17, a semiconductor layer 61 is formed as shown in FIG. 16. Specifically, the semiconductor layer 61 is formed on the surface of the tunnel insulating film 43.

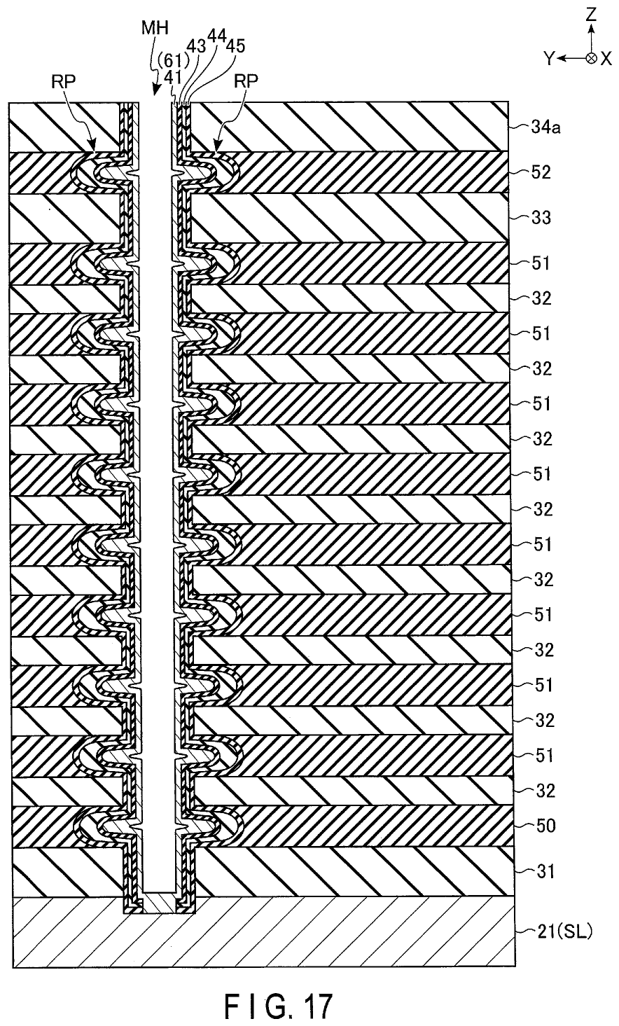

In the processing of step S18, the slimming processing of the semiconductor layer 61 is performed as shown in FIG. 17. Specifically, the wet-etching is performed via the memory hole MH so as to remove parts of the semiconductor layer 61 that are exposed on the side surface of the memory hole MH. The semiconductor layer 61 after being subjected to the slimming processing is referred to as the semiconductor layer 41. That is, the semiconductor layer 61 is slimmed to be formed into the semiconductor layer 41.

As with the processing of step S15, in the semiconductor layer 61, the etching proceeds faster at or near the corner part CP of each guard region GD than in each pillar second region MP2; and as a result, the semiconductor layer 41 is formed to be thinner there. Similarly, in the semiconductor layer 61, the etching proceeds faster in each pillar second region MP2 than in each cell region CE; and as a result, the semiconductor layer 41 is formed to be thinner there. In other words, the semiconductor layer 41 in the cell regions CE may be formed thicker than in the other parts, and the semiconductor layer 41 at or near the corner parts CP in the guard regions GD may be formed thinner than in the other parts.

For example, in each cell region CE, the semiconductor layer 41 becomes thicker as this comes closer to the recess of the concave part. In other words, for example, in the cell region CE, the closer to the middle of the pillar first region MP1, the thicker the semiconductor layer 41.

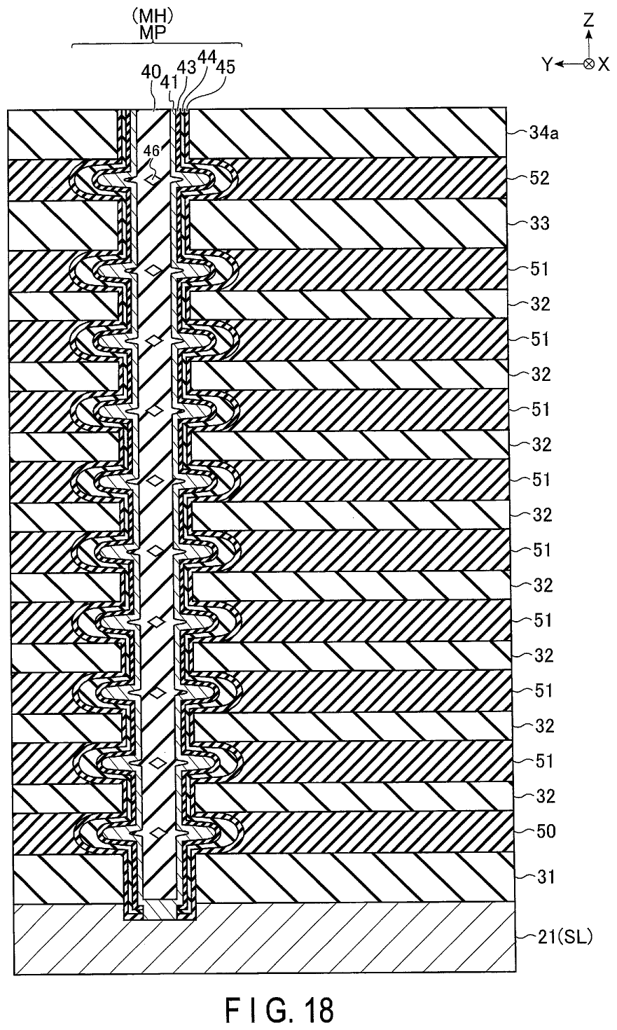

In the processing of step S19, the core member 40 is formed as shown in FIG. 18. Specifically, the inside of the memory hole MH is charged with the core member 40. For example, the core member 40 is formed to have substantially the same thickness regardless of whether that is in the middle of the pillar first region MP1 or in the end of the pillar first region MP1. When being formed to have substantially the same thickness, for example, at the time when the regions having no recesses of the concave parts of the semiconductor layer 41 are charged and closed, the regions having the recesses of the concave parts are not completely charged yet; therefore, these regions remain as the voids 46. Hence, the central part of each pillar first region MP1 may have the void 46. The memory pillar MP is thus formed.

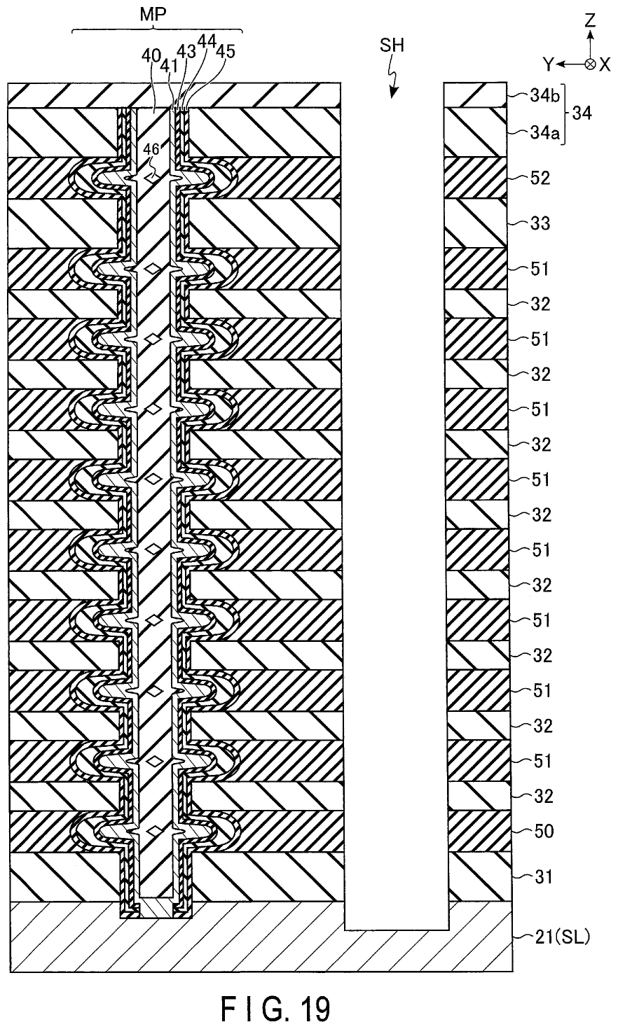

In the processing of step S20, a slit is formed as shown in FIG. 19. Specifically, first, an insulating layer 34b is formed on the upper surface of the insulating layer 34a and the memory pillar MP. A layer including the insulating layer 34a and the insulating layer 34b may be referred to hereinafter as the insulating layer 34.

Subsequently, the slit SH is formed in a region where the member SLT is to be formed. Specifically, a mask having openings in regions corresponding to the slits SH is formed by photolithography or the like, and the slits SH are then formed by anisotropic etching using the mask. The slits SH divide, for example, the insulating layers 31 to 34 and the sacrificial members 50 to 52, respectively.

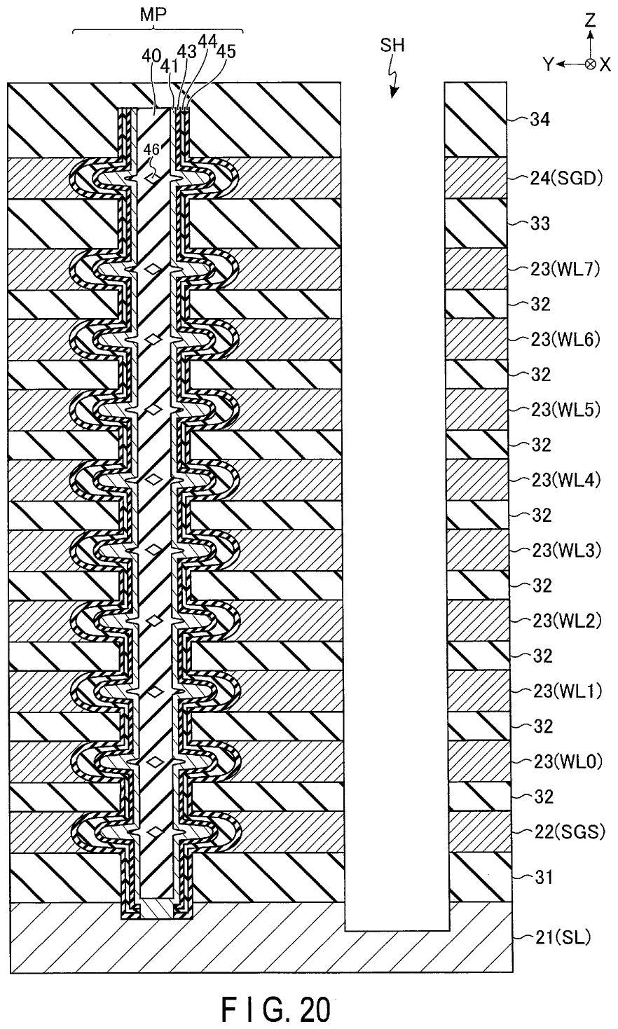

In the processing of step S21, replacement processing is performed as shown in FIG. 20. Specifically, for example, the sacrificial members 50 to 52 are selectively removed via the slit SH by the wet-etching using a hot phosphoric acid. As a result, spaces are formed in the regions where the conductive layers 22 to 24 are to be formed. The three-dimensional structure of the structure in which the sacrificial members 50 to 52 are removed is maintained by the memory pillars MP.

Subsequently, the spaces where the sacrificial members 50 to 52 are removed is charged with the conductor via the slit SH. After that, the conductor formed inside the slit SH is removed by etch-back processing. As a result, the conductive layer 22 functioning as the select gate line SGS, the conductive layers 23 functioning as the word lines WL0 to WL7, and the conductive layer 24 functioning as the select gate line SGD are formed, respectively. The conductive layers 22 to 25 formed in this step may contain a barrier metal. In this case, in the formation of the conductive layers after the removal of the sacrificial members 50 to 52, tungsten is formed after films of titanium nitride are formed as the barrier metal, for example.

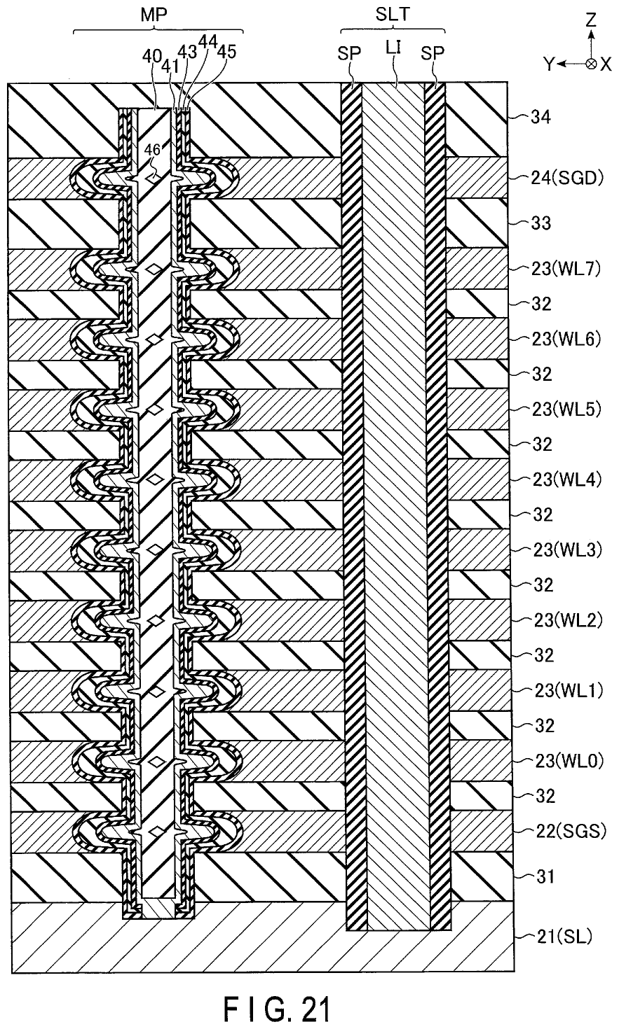

In the processing of step S22, the member SLT is formed as shown in FIG. 21. Specifically, first, an insulating part (a spacer SP) is formed so as to cover the side surface and the bottom surface of the slit SH. Then, a part of the spacer SP provided at the bottom of the slit SH is removed, and thereby a part of the conductive layer 21 is exposed to the bottom of the slit SH. Then, a conductor (the contact LI) is formed in the slit SH. The conductor formed outside the slit SH is removed, for example, by CMP. Further, the members SHE are formed for dividing the conductive layer 24 in the stacked interconnect structure into a plurality of parts.

Subsequently, the insulating layer 34 on the memory pillars MP is removed and the contacts CV are provided on the memory pillars MP. Next, the conductive layers 25, which function as the bit lines BL, are formed on the contacts CV.

The stacked interconnect structure in the memory cell array 10 is formed by the manufacturing steps of the semiconductor memory device 1 according to the first embodiment described above. Note that the manufacturing steps described above are merely an example, and are not limited thereto. For example, other steps may be inserted between the manufacturing steps, or some of the steps may be omitted or integrated. Further, the order of the manufacturing steps may be changed as long as no problem occurs.

[1-3] Advantages (Effects) of First Embodiment

According to the semiconductor memory device 1 of the first embodiment described above, the data retention property of the semiconductor memory device 1 can be improved, thereby providing a high-quality semiconductor memory device. Further, according to the semiconductor memory device 1 of the first embodiment, it is possible to manufacture the stacked interconnect structure having a thin thickness. Hereinafter, the detailed effects of the semiconductor memory device 1 according to the first embodiment will be described.

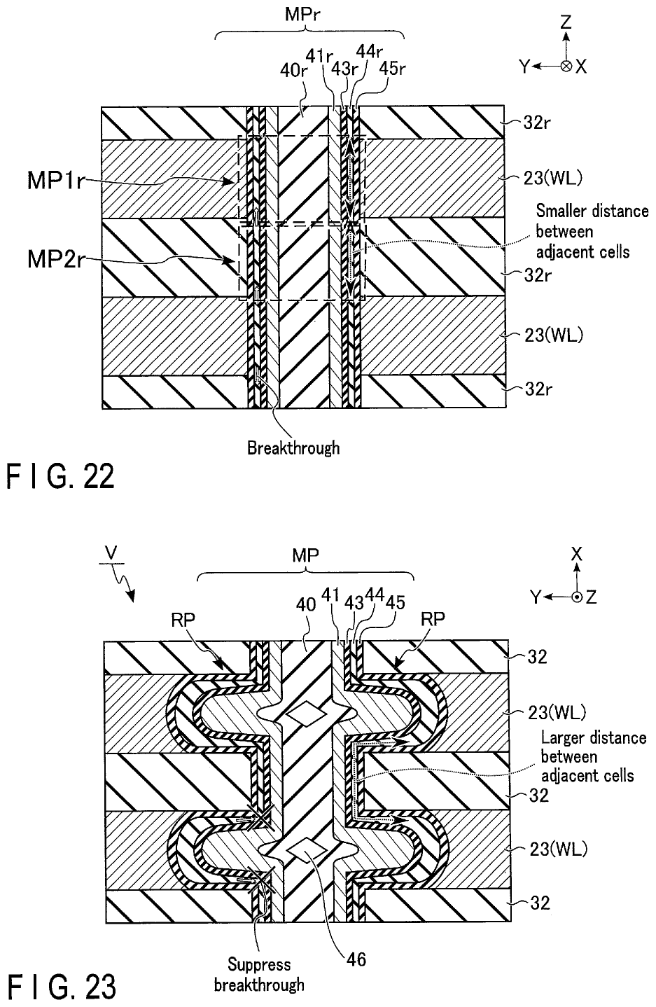

First, with reference to FIG. 22, the semiconductor memory device 1 according to a comparative example of the first embodiment will be described. The semiconductor memory device 1, the memory pillar MP, the pillar first region MP1, and the pillar second region MP2 according to the comparative example of the first embodiment may be referred to as a semiconductor memory device 1r, a memory pillar MPr, a pillar first region MP1r, and a pillar second region MP2r, respectively, for the sake of distinguishing them from the semiconductor memory device 1, the memory pillar MP, the pillar first region MP1, and the pillar second region MP2 of the first embodiment.

Similarly, the core member 40, the semiconductor layer 41, the tunnel insulating film 43, the insulating film 44, the block insulating film 45, and the insulating layer 32 according to the comparative example of the first embodiment may be referred to as a core member 40r, a semiconductor layer 41r, a tunnel insulating film 43r, an insulating film 44r, a block insulating film 45r, and an insulating layer 32r, respectively. FIG. 22 shows an example of the cross-sectional structure of the memory pillar MPr in the semiconductor memory device it according to the comparative example of the first embodiment. FIG. 22 shows the same region as that in FIG. 5.

Different from the memory pillar MP, the memory pillar MPr has substantially the same diameter in the pillar first region MP1r and in the pillar second region MP2r. In other words, the memory pillar MPr extends along the Z direction, and has no parts protruding in the XY direction.

That is, as shown in FIG. 22, in the memory pillar MPr, the thicknesses of the core member 40r, the semiconductor layer 41r, the tunnel insulating film 43r, the insulating film 44r, and the block insulating film 45r do not depend on the Z axis. That is, the thicknesses of the core member 40r, the semiconductor layer 41r, the tunnel insulating film 43r, the insulating film 44r, and the block insulating film 45r are substantially constant regardless of whether they are in the middle of the pillar first region MP1r or in the end of the pillar first region MP1r. Similarly, the thicknesses of the core member 40r, the semiconductor layer 41r, the tunnel insulating film 43r, the insulating film 44r, and the block insulating film 45r are substantially constant regardless of whether they are in the middle of the pillar second region MP2r or in the end of the pillar second region MP2r.

In this manner, the semiconductor memory device 1r according to the comparative example, the thickness of the insulating film 44r is the same both in the pillar first region MP1r and in the pillar second region MP2r. Further, the insulating film 44r in the pillar first region MP1r and the insulating film 44r in the pillar second region MP2r are aligned along the Z axis.

Due to such a structure, in the semiconductor memory device 1r according to the comparative example, when data is written to the insulating film 44r (charge storage layer) of the pillar first region MP1r, for example, the electric charge charged on the insulating film 44r may leak to the insulating film 44r of the adjacent pillar second region MP2r having substantially the same thickness along the Z axis.

Such a phenomenon that electric charge accumulated in the charge storage layer leaks to the adjacent charge storage layer may be referred to as “breakthrough” of electric charge, hereinafter. The breakthrough of electric charge is caused, for example, over time or by deterioration of the charge storage layer. When the breakthrough of electric charge occurs, the data cannot be read correctly, which results in deterioration of the data retention property.

The insulating film 44r is required to have a certain thickness to function as the charge storage layer. For example, in the structure of the semiconductor memory device 1r, when the insulating film 44r is formed to be thinner to prevent the breakthrough of data, the insulating film 44r cannot function as the charge storage layer. Consequently, the semiconductor memory device is required to have a structure that prevents the breakthrough of data and allows the charge storage layer to function.

On the other hand, FIG. 23 shows an example of the cross-sectional structure of the memory pillar MP in the semiconductor memory device 1 according to the first embodiment. FIG. 23 shows the same region as that in FIG. 5. In the semiconductor memory device 1 according to the first embodiment, the memory pillar MP has the parts protruding in the XY direction while extending along the Z direction. The memory pillar MP has a larger diameter in each pillar first region MP1 than that in each pillar second region MP2. Further, in the semiconductor memory device 1 according to the first embodiment, the insulating film 44 of each cell region CE may be formed to be thicker than in the other parts, and the insulating film 44 at or near the corner part CP of each guard region GD may be formed to be thinner than in the other parts. That is, the insulating film 44 of the cell region CE is sandwiched by the insulating films 44 each having a thinner thickness at or near the corner parts CP. Further, the insulating film 44 in each cell region CE and the insulating film 44 in each pillar second region MP2 do not aligned along the Z axis.

Due to such a structure, the insulating film 44 can suppress the breakthrough of electric charge more, compared with the insulating film 44r. This will be specifically described below. In the memory cell transistor MT, the charge is mainly accumulated in the insulating film 44 in each cell region CE located near the word line. Since the insulating film 44 in the cell region CE is maintained to be thick, this film can function as the charge storage layer without any problem. The electric charge charged in the insulating film 44 in the cell region CE is blocked by the insulating film 44 formed to be thinner at or near the corner part CP, which makes it difficult to cause the breakthrough. This is because the electric charge charged in the insulating film 44 in each cell region CE needs to pass through the insulating film 44 that is thinly formed at or near the corner part CP when the electric charge leaks to the insulating film 44 of the pillar second region MP2.

Further, as described above, the insulating film 44 has a part having a difference in thickness by 2 nm or more in at least one set of the guard region GD and the cell region CE, for example. Since the difference in thickness is 2 nm or more, the insulating film 44 included in the semiconductor memory device 1 can effectively suppress the breakthrough of electric charge.

In this manner, by forming the both ends of the charge storage layer to be locally thin, the semiconductor memory device 1 according to the first embodiment can prevent the breakthrough of data and improve the data retention property.

Further, in the semiconductor memory device 1 according to the first embodiment, the stacked interconnect structure can be manufactured to be thinner by forming the interlayer insulating film to be thinner than that of the semiconductor memory device it according to the comparative example. Specifically, as shown in FIG. 23, the thickness of the insulating layer 32r of the semiconductor memory device it according to the comparative example is thicker than that of the insulating layer 32.

In the semiconductor memory device it according to the comparative example, the insulating film 44r in each pillar first region MP1 and the insulating film 44r in each pillar second region MP2 are aligned along the Z axis. In each pillar first region MP1r of the semiconductor memory device 1r, the distance between the conductive layer 23 as an electrode and the insulating film 44r is substantially the same over the entire Z axis. That is, the insulating film 44r in the pillar first region MP1r has a function of storing electric charge over the entire area along the Z axis. The insulating film 44r does not have the structure that suppresses leakage of accumulated electric charge, which each guard region GD in the semiconductor memory device 1 has. Hence, the part of the semiconductor memory device 1r that functions as the memory cell transistor MT covers the entire pillar first region MP1r.

For this reason, as shown in FIG. 22, in the semiconductor memory device 1r, the distance between the adjacent memory cell transistors MT (between the pillar first regions MP1r) may be shorter. When the distance between the adjacent memory cell transistors MT becomes shorter, the distance between the insulating films 44r included in the respective adjacent memory cell transistors MT also becomes shorter. That is, the distance between the electric charges accumulated in the respective memory cell transistors MT becomes closer. When the distance between the accumulated electric charges becomes shorter, problems such as the breakthrough and interference of electric charge may occur. Consequently, it may be required to separate the memory cell transistors MT from each other by forming the insulating layers 32 to be thicker. If the insulating layer 32 is formed to be thicker, it might be difficult to manufacture the stacked interconnect structure of the semiconductor memory device 1r to be thinner.

The semiconductor memory device 1 according to the first embodiment is devised such that the distance between the memory cell transistors MT is prevented from being close to each other. In the semiconductor memory device 1 according to the first embodiment, the memory pillar MP has parts protruding in the XY direction while extending along the Z direction. The memory pillar MP has a larger diameter in each pillar first region MP1 than that in each pillar second region MP2. The insulating film 44 has a shape corresponding to the shape of such a memory pillar MP. That is, the insulating film 44 has parts protruding in the XY direction.

The semiconductor memory device 1 includes a guard region GD between each cell region CE and each pillar second region MP2. Therefore, the distance between the insulating films 44 included in the respective adjacent cell regions CE is longer by the guard regions GD. Each guard region has a component that extends in the X direction and the Y direction. In the semiconductor memory device 1, the distance between the adjacent cell regions CE can be increased by the components extending in the X direction and the Y direction. In other words, the semiconductor memory device 1 can increase the distance between the adjacent memory cell transistors MT by providing the insulating film 44 so as to extend in the X direction and the Y direction in each guard region GD.

That is, the semiconductor memory device 1 can secure the distance between the parts where the electric charge is accumulated in the memory cell transistors MT without providing the insulating layers 32 to be thicker. Accordingly, the semiconductor memory device 1 allows the insulating layers 32 to be thinner along the Z axis as compared with the semiconductor memory device 1r, thereby manufacturing the stacked interconnect structure to be thinner.

### [2] Modification of First Embodiment

In the semiconductor memory device 1 according to the first embodiment described above, there has been exemplified the case in which the thickness of the tunnel insulating film 43 is substantially the same regardless of whether that is in the middle of the pillar first region MP1 or in the end of the pillar first region MP1. However, the thickness of the tunnel insulating film 43 of the semiconductor memory device 1 may be changed depending on the Z axis in each pillar first region MP1.

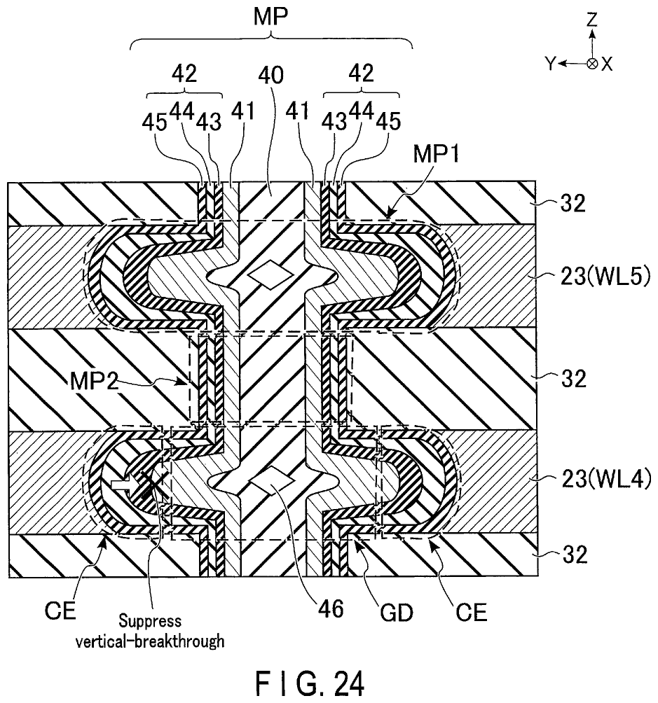

FIG. 24 shows an example of the memory pillar MP in the semiconductor memory device 1 according to a modified example of the first embodiment. FIG. 24 shows a part of the memory pillar MP, and shows the respective structures of each conductive layer 23 and each region in the memory pillar MP that intersects this conductive layer 23. Although not shown in the drawing, the region of each memory pillar MP that intersects the conductive layer 22 or 24 may or may not have the same structure as that of the region that intersects the conductive layers 23 as described below. Regarding the shape of the pillar first region MP1, the part intersecting each conductive layer 23 will be mainly described, hereinafter.

As shown in FIG. 24, the tunnel insulating film 43 is provided so as to be thicker in the middle of the pillar first region MP1 than that in the end of the pillar first region MP1. In other words, the tunnel insulating film 43 is thicker in the middle of the pillar first region MP1 and thinner in the end of the pillar first region MP1, and covers the circumference of the semiconductor layer 41. Furthermore, the tunnel insulating film 43 is formed to be thicker in the cell region CE than in the guard region GD.

The tunnel insulating film 43 of the semiconductor memory device 1 according to the modified example is provided to be thicker in the middle of the pillar first region MP1 than in the end of the pillar first region MP1, thereby suppressing vertical-breakthrough of electric charge. Vertical-breakthrough of electric charge is a phenomenon that, for example, when electric charge is accumulated in the insulating film 44 of the pillar first region MP1, the electric charge accumulated in the insulating film 44 passes through the tunnel insulating film 43 and leaks to the semiconductor layer 41. The vertical-breakthrough of electric charge may be caused, for example, over time or by deterioration of the tunnel insulating film 43 and/or the insulating film 44, or the like. When the vertical-breakthrough of electric charge occurs, data cannot be read correctly, which results in deterioration of the data retention property.

When the tunnel insulating film 43 is provided so as to have substantially the same thickness, an electric field may be concentrated on the semiconductor layer 41 in the middle of the pillar first region MP1. This is because the semiconductor layer 41 in the central part of each pillar first region MP1 is located closer to the word line (each of the conductive layers 22 to 24) than in the other parts. When the electric field is concentrated in the middle of the pillar first region MP1, charge transition might be performed mostly in the middle of the pillar first region MP1. When the charge transition occurs mostly in the middle of the pillar first region MP1, deterioration of the tunnel insulating film 43 and/or the insulating film 44 in the middle of the pillar first region MP1 might be promoted. Deterioration of the tunnel insulating film 43 and/or the insulating film 44 might cause the vertical-breakthrough of electric charge.

To cope with this, in the semiconductor memory device 1 according to the modified example, the tunnel insulating film 43 in the middle of the pillar first region MP1 is provided so as to be thicker. By forming the tunnel insulating film 43 to be thicker in the middle of the pillar first region MP1, it is possible to suppress intensive transition of electric charge from the semiconductor layer 41 to the insulating film 44 in the central part. In addition, concentration of the electric field from the word line to the semiconductor layer 41 in the middle of the pillar first region MP1 can be reduced, thereby suppressing the intensive transition of electric charge. Suppressing the intensive transition of electric charge can also suppress the deterioration of the tunnel insulating film 43 and/or the insulating film 44. Accordingly, the semiconductor memory device 1 according to the modified example can suppress the vertical-breakthrough of electric charge more as compared with the case of providing the tunnel insulating film 43 to have substantially the same thickness.

In the semiconductor memory device 1 according to the first embodiment described above, the case in which the core member 40 is formed to have substantially the same thickness has been exemplified. However, the thickness of the core member 40 included in the semiconductor memory device 1 may vary depending on the Z axis, for example, due to the manufacturing convenience or the like.

As aforementioned, the core member 40 is formed in the processing of step S19. At this time, a gas including the material is introduced above the memory hole MH. Therefore, the core member 40 may be formed faster in the upper part of the memory hole MH than in the lower part of the memory hole MH. That is, the pillar first regions MP1 and the pillar second regions MP2 located in the upper part of the memory hole MH may be closed before the lower part of the memory hole. MH. At this time, the lower part of the memory hole MH remains as a vertically elongated void or seam. The vertically elongated void extends, for example, through the pillar first regions MP1 and the pillar second regions MP2. In this case, the thickness of the core member 40 included in the semiconductor memory device 1 according to the modified example varies depending on the Z axis.

### [3] Second Embodiment

The semiconductor memory device 1 according to the second embodiment will be described, hereinafter. The semiconductor memory device 1 according to the second embodiment is different from the semiconductor memory device 1 according to the first embodiment. For the sake of distinction from the semiconductor memory device 1 of the first embodiment, the semiconductor memory device 1 of the second embodiment may be referred to hereinafter as a semiconductor memory device 1b. For the sake of distinction from the memory pillar MP and the insulating film 44 of the first embodiment, the memory pillar MP and the insulating film 44 of the second embodiment may be referred to as a memory pillar MPb and an insulating film 44b, respectively. The insulating film 44b is used as a charge storage layer for the memory cell transistor MT. The pillar first region MP1, the pillar second region MP2, the cell region CE, the guard region GD, and the corner part CP of the second embodiment may be referred to as a pillar first region MP1b, a pillar second region MP2b, a cell region CEb, a guard region GDb, and a corner part CPb, respectively.

The semiconductor memory device 1b is different from the semiconductor memory device 1 according to the first embodiment (FIG. 5) mainly in the structure of the insulating film 44b of the memory pillar MPb. The memory pillar MPb has no insulating film 44b in the pillar second region MP2b. The other structures of the second embodiment are almost the same as those of the first embodiment. Regarding the semiconductor memory device 1b of the second embodiment, the differences between the semiconductor memory device 1b and the semiconductor memory device 1 according to the first embodiment will be mainly described, hereinafter.

[2-1] Cross-Sectional Structure of Memory Cell Array 10

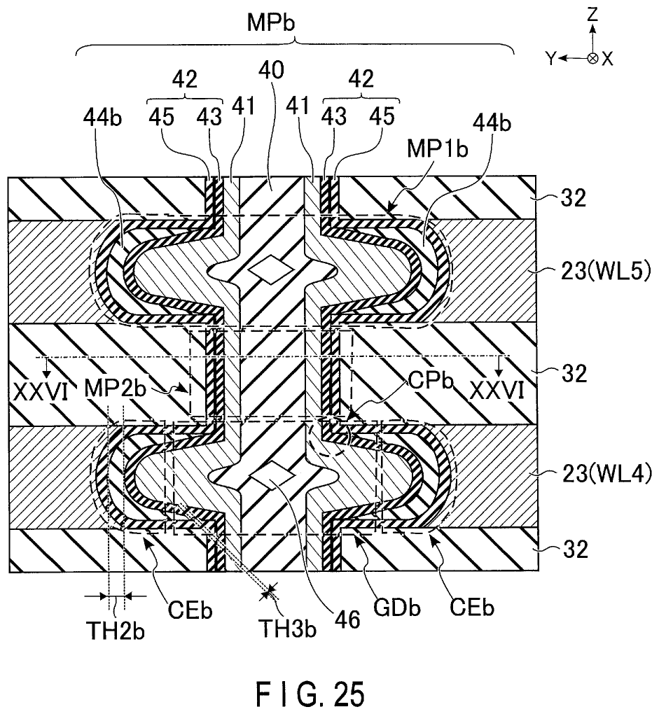

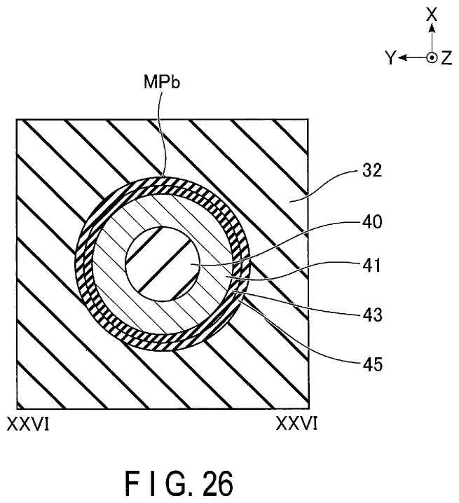

The details of the structure of the insulating film 44b in the memory pillar MPb will be described with reference to FIG. 25 and FIG. 26. FIG. 25 shows an example of the cross-sectional structure of the memory pillar MPb in the semiconductor memory device 1b according to the second embodiment. FIG. 25 shows a cross section of the same region as that in FIG. 4 of the first embodiment.

FIG. 25 shows a part of the memory pillar MPb, and shows the structure of each of the conductive layers 23 and the structure of each of the regions in the memory pillar MPb that intersect the conductive layers 23. Although not shown in the drawing, the region in the memory pillar MPb that intersects the conductive layer 22 or 24 may or may not have the same structure as that of each of the regions that intersect the conductive layers 23 as described below. Regarding the shape of the pillar first region MP1b, a part intersecting each of the conductive layers 23 will be mainly described, hereinafter.

As with the first embodiment, the memory pillar MPb of the second embodiment has a part protruding in the XY direction while extending along the Z direction. The part protruding in the XY direction is the pillar first region MP1b. That is, the diameter of the pillar first region MP1b is larger than the diameter of the pillar second region MP2b.

The pillar first region MP1b includes the core member 40, the semiconductor layer 41, the tunnel insulating film 43, the insulating film 44b, and the block insulating film 45. The pillar first region MP1b may have the void 46. The pillar second region MP2b includes the core member 40, the semiconductor layer 41, the tunnel insulating film 43, and the block insulating film 45.

Since the structures of the core member 40, the void 46, the semiconductor layer 41, and the tunnel insulating film 43 are the same as those in the first embodiment, the description thereof will be omitted. The semiconductor memory device 1b according to the second embodiment may have a structure that has no core member 40 and has the semiconductor layer 41 embedded to the central part.

The insulating film 44b is provided on the side surface of the tunnel insulating film 43 in each cell region CEb. The insulating film 44b is not provided on the side surface of the tunnel insulating film 43 in each pillar second region MP2b. In the guard region GDb, the insulating film 44b has a region provided on the side surface of the tunnel insulating film 43 and a region not provided thereon. Specifically, in the guard region GDb, the insulating film 44b is provided in parts in contact with the cell region CEb and near the cell region CEb, but is not provided in parts in contact with the pillar second region MP2b and/or near the pillar second region MP2b.

In the pillar first region MP1b, the thickness of the insulating film 44b depends on the Z axis. Specifically, in the middle of the pillar first region MP1b, the insulating film 44b is formed to be thicker than at or near the guard region GDb. In the guard region GDb, for example, the thickness of the insulating film 44b gradually decreases from the parts in contact with the cell region CEb toward the parts in contact with the pillar second region MP2b, and the insulating film 44b has no thickness in the parts in contact with the pillar second region MP2b and/or near the pillar second region MP2b. That is, in the pillar first region MP1b, the insulating film 44b becomes thicker as this comes closer to the middle of the pillar first region MP1b, and becomes thinner as this comes closer to the end of the pillar first region MP1b, in such a manner as to cover the circumference of the tunnel insulating film 43.

The insulating film 44b has the thinnest part in the guard region GDb, and the thickness of this part may be referred to as a charge storage layer thickness TH3b. For example, the part where the insulating film 44b is formed to be the thinnest may include the corner part CPb. The insulating film 44b at the corner part CPb is easily provided to be thinner.

The insulating film 44b has the thickest part in the cell region CEb, and the thickness of this part may be referred to as a charge storage layer thickness TH2b. No insulating film 44b is provided in the pillar second region MP2b. For example, the charge storage layer thickness TH2b may be larger by 2 nm or more than the charge storage layer thickness TH3b. For example, in at least one set of the guard region GDb and the cell region CEb, the insulating film 44b has a part having a difference in thickness by 2 nm or more.

The block insulating film 45 is provided on the side surface of the insulating film 44b. Further, the block insulating film 45 is provided on the side surface of the tunnel insulating film 43 in parts where the insulating film 44b is not provided. The block insulating film 45 is continuously provided in the pillar first region MP1b and in the pillar second region MP2b. As with the first embodiment, the block insulating film 45 in the cell region CEb and the block insulating film 45 in the pillar second region MP2b are not adjacent to each other along the Z axis.

In the pillar first region MP1b and the pillar second region MP2b, the thickness of block insulating film 45 does not depend on the Z axis. That is, the thickness of the block insulating film 45 is substantially the same in the middle of the pillar first region MP1b, the end of the pillar first region MP1b along the Z axis, the middle of the pillar second region MP2b, and the end of the pillar second region MP2b.

FIG. 26 is a cross-sectional view taken along line XXVI-XXVI of FIG. 25, and shows an example of the cross-sectional structure of the memory pillar MPb in the semiconductor memory device 1b according to the second embodiment. Specifically, FIG. 26 shows the cross-sectional structure of the memory pillar MPb in a layer parallel to the surface of the semiconductor substrate 20 and including the insulating layer 32.

In the cross section including the insulating layer 32, the core member 40 is provided in the central part of the memory pillar MPb. The semiconductor layer 41 surrounds the side surface of the core member 40. The tunnel insulating film 43 surrounds the side surface of the semiconductor layer 41. The block insulating film 45 surrounds the side surface of the semiconductor layer 41. The insulating layer 32 surrounds the side surface of the block insulating film 45. Each of the tunnel insulating film 43 and the block insulating film 45 contains, for example, silicon oxide. The insulating film 44 contains, for example, silicon nitride.

The structure of the insulating layer 31 and the memory pillar MPb in a layer parallel to the surface of the semiconductor substrate 20 and including the insulating layer 31, the structure of the insulating layer 33 and the memory pillar MPb in a layer parallel to the surface of the semiconductor substrate 20 and including the insulating layer 33, and the structure of the insulating layer 34 and the memory pillar MPb in a layer parallel to the surface of the semiconductor substrate 20 and including the insulating layer 34 may be the same respectively as the structure of the insulating layer 32 and the memory pillar MPb in a layer parallel to the surface of semiconductor substrate 20 and including the insulating layer 32.

### [3] Manufacturing Method of Semiconductor Memory Device 1b

The manufacturing method of the semiconductor memory device 1b according to the second embodiment is different from the manufacturing method of the semiconductor memory device 1 according to the first embodiment mainly in the formation of the insulating film 44b of the memory pillar MPb.

In the manufacturing method of the semiconductor memory device 1b according to the second embodiment, for example, the processing of step S10 to the processing of step S17 are sequentially performed as in the first embodiment. The semiconductor memory device 1b according to the second embodiment is different from the first embodiment mainly in the amount of etching on the insulating film 60 in the processing of step S15.

In the semiconductor memory device 1b according to the second embodiment, in the processing of step S15, the etching processing is performed on the insulating film 60. Specifically, wet-etching is performed via the memory hole MH so as to remove a part of the insulating film 60 exposed on the side surface of the memory hole MH. At this time, in the semiconductor memory device 1b according to the second embodiment, the etching processing is performed for a longer time than in the first embodiment, and the insulating film 60 is etched more than in the first embodiment. The insulating film 60 after being subjected to the etching processing is referred to as an insulating film 44b. That is, the insulating film 60 is etched to be formed into the insulating film 44b.

As with the first embodiment, the insulating film 60 is etched faster at or near the corner parts CPb of the guard region GDb than in the pillar second region MP2b. In the pillar second region MP2b, the insulating film 60 is etched faster than in the cell region CEb.

Hence, as the etching proceeds, the insulating film 60 at or near the corner parts CPb of the guard region GDb is first etched, and the tunnel insulating film 43 is exposed. Subsequently, the insulating film 60 in the pillar second region MP2b is etched and the tunnel insulating film 43 is exposed. At this time, the etching is stopped. As a result, the insulating film 44b is formed in parts of the guard region GDb and in the cell region CEb, where the insulating film 60 had a concave shape. In other words, the insulating film 44b is formed neither at or near the corner parts CPb of the guard region. GDb nor in the pillar second region MP2b.

As with the first embodiment, the insulating film 44b in the cell region CEb may be formed to be thicker than in the other parts, and the insulating film 44b located closer to the corner parts CPb of the guard region GDb may be formed to be thinner than in the other parts.

For example, in the cell region CEb, the insulating film 44b becomes thicker as this comes closer to the recess of the concave part. This is because the closer to the recess of the concave part, the more difficult the wet-etching solution to reach. In other words, for example, in the cell region CEb, the closer to the middle of the pillar first region MP1b, the thicker the insulating film 44b.

The other processing of the second embodiment is the same as that of the first embodiment; therefore, description thereof will be omitted.

[3-3] Advantages (Effects) of Second Embodiment

As with the first embodiment, the semiconductor memory device 1b according to the second embodiment described above can improve the data retention property of the semiconductor memory device 1b, thereby providing a high-quality semiconductor memory device. Further, as with the first embodiment, according to the semiconductor memory device 1b of the second embodiment, it is possible to manufacture the stacked interconnect structure having a thinner thickness.

First, as with the first embodiment, in the semiconductor memory device 1b according to the second embodiment, the insulating film 44b is formed to be thicker in the cell region CEb. The semiconductor memory device 1b has no insulating film 44b in the pillar second region MP2b.

In this manner, the semiconductor memory device 1b according to the second embodiment can prevent the breakthrough of data and can improve the data retention property by discontinuously providing the charge storage layers in the adjacent memory cell transistors MT.

Further, as with the first embodiment, in the semiconductor memory device 1b according to the second embodiment, it is possible to manufacture the stacked interconnect structure to be thinner by providing the interlayer insulating film so as to be thinner than that in the semiconductor memory device 1r according to the comparative example.

In the semiconductor memory device 1b according to the second embodiment, the charge storage layers in the adjacent memory cell transistors MT are discontinuous; therefore, even when the interlayer insulating film is formed to be thinner, the breakthrough or interference of the electric charge hardly occurs. Accordingly, the semiconductor memory device 1b allows the interlayer insulating films to be thinner along the Z axis as compared with those in the semiconductor memory device 1r, thereby manufacturing the stacked interconnect structure to be thinner.

### [4] Other Modifications, Etc.

In the first to second embodiments, the semiconductor memory devices 1 to 1b may each have another structure. The structure in the modified example of the first embodiment can also be applied to the second embodiment. The structure shown in the modified example of the first embodiment can be applied to the first embodiment and the second embodiment even in the case of applying only a part of this structure or in combination with a plurality of parts thereof.

The term “connection” in the present specification indicates “being electrically connected”, and does not exclude, for example, such a case that interposes another element in between. This “being electrically connected” may be established via an insulator as long as this connection can operate in the same manner as an electrically connected one.

The first and second embodiments described above have been presented by way of example only, and are not intended to limit the scope of the invention. The first and second embodiments may be embodied in a variety of other forms, and various omissions, substitutions and variations may be made without departing from the spirit of the invention. The first and second embodiments and modifications thereof are included in the scope and spirit of the invention, and are included in the scope of the claimed inventions and their equivalents.

1. A semiconductor memory device comprising:
a substrate;
a layer stack in a first direction above the substrate; and
a pillar penetrating the layer stack in the first direction,
wherein
the layer stack includes:
a first conductor; and
a first insulator on an upper surface of the first conductor along the first direction,
the pillar includes a second insulator extending along an extending direction of the pillar,
the second insulator includes a first part located in a first layer in which the first conductor is located and a second part located in a second layer in which the first insulator is located, the first part including a portion thicker than the second part, and
a diameter of the pillar in the first layer is larger than a diameter of the pillar in the second layer.

2. The semiconductor memory device according to claim 1, wherein
the first part includes a portion thicker by 2 nm or more than the second part.

3. The semiconductor memory device according to claim 1, wherein
a difference between a maximum thickness and a minimum thickness in the first part is 2 nm or more.

4. The semiconductor memory device according to claim 1, wherein
the first part includes a first region at or near a middle of the first part in the first direction and a second region at or near an end of the first part in the first direction, and
the first region is thicker than the second region.

5. The semiconductor memory device according to claim 4, wherein
the first region includes a portion thicker by 2 nm or more than the second region.

6. The semiconductor memory device according to claim 4, wherein
the first region includes a portion thicker than the second part, and
the second part includes a portion thicker than the second region.

7. The semiconductor memory device according to claim 4, wherein
the first region includes a portion closer to the first conductor than the second region is.

8. The semiconductor memory device according to claim 1, wherein
the first conductor is thicker than the first insulator in the first direction.

9. The semiconductor memory device according to claim 1, wherein
the second insulator is a charge storage layer.

10. The semiconductor memory device according to claim 1, wherein
the second insulator contains silicon nitride.

11. The semiconductor memory device according to claim 1, wherein
the first conductor is a word line.

12. The semiconductor memory device according to claim 1, wherein
the pillar further includes:
a first semiconductor inward of the second insulator and extending along the extending direction of the pillar;
a third insulator between the first semiconductor and the second insulator and extending along the extending direction of the pillar; and
a fourth insulator between the second insulator and the layer stack and extending along the extending direction of the pillar, and
a portion of the first semiconductor in the first layer is thicker than a portion of the first semiconductor in the second layer.

13. The semiconductor memory device according to claim 1, wherein
the pillar further includes a third insulator inward of the second insulator and extending along the extending direction of the pillar, and
a region of the third insulator in the first layer that is located at or near a middle of the third insulator thereof in the first direction is thicker than a region of the third insulator in the first layer that is located at or near an end of the third insulator in the first direction.

14. The semiconductor memory device according to claim 13, wherein
the third insulator is a tunnel insulating film.

15. The semiconductor memory device according to claim 13, wherein
the third insulator contains silicon oxide.

16. A semiconductor memory device comprising:
a substrate;
a layer stack in a first direction above the substrate; and
a pillar penetrating the layer stack in the first direction,
wherein,
the layer stack includes:
a first conductor; and
a first insulator on a an upper surface of the first conductor along the first direction,
the pillar includes a second insulator located in a first layer in which the first conductor is located, the second insulator extending along an extending direction of the pillar,
the second insulator includes a first region at or near a middle of the second insulator in the first direction and a second region at or near an end of the second insulator in the first direction,
the second insulator does not include a part located in a second layer in which the first insulator is located,
the first region is thicker than the second region, and
a diameter of the pillar in the first layer is larger than a diameter of the pillar in the second layer.

17. The semiconductor memory device according to claim 16, wherein
the first region includes a portion thicker by 2 nm or more than the second region.

18. A method for manufacturing a semiconductor memory device, comprising:
forming a layer stack in which a sacrificial member and a first insulator are alternately stacked in a first direction;
forming a memory hole concentric with a first axis extending through the layer stack;
removing a part of the sacrificial member via the memory hole;
forming a second insulator in a part of a first space formed by removal of the sacrificial member and in a part of the memory hole;
removing a part of the second insulator via the first space and the memory hole;
forming a first semiconductor in a part of the first space and a part of the memory hole;
removing a part of the first semiconductor via the first space and the memory hole;
forming a slit dividing the layer stack;
selectively removing the sacrificial member via the slit;
forming a first conductor in a part of a space formed by removal of the sacrificial member; and
forming a third insulator in the slit,
wherein
the second insulator includes a first part located in a first layer in which the first conductor is located and a second part located in a second layer in which the first insulator is located, the first part including a portion thicker than the second part, and
the first part is located farther from the first axis than the second part is.

19. The method according to claim 18, wherein
the first part includes a first region at or near a middle of the first part in the first direction and a second region at or near an end of the first part in the first direction, and
the first region includes a portion thicker by 2 nm or more than the second region.
